(19) United States
(12) Patent Application Publication
(10) Pub. No.: US 2004/0016987 A1
(43) Pub. Date: Jan. 29, 2004

(54) Semiconductor device with insulator and manufacturing method therefor

(75) Inventors: Mahito Sawada, Hyogo (JP); Hiroshi Tobimatsu, Hyogo (JP); Yoshio Hayashide, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/335,943

(22) Filed: Jan. 3, 2003

(30) Foreign Application Priority Data
Jul. 10, 2002 (JP) 2002-201396

(51) Int. Cl. H01L 21/76; H01L 29/00

(52) U.S. Cl. 257/510; 438/435; 257/513

(57) ABSTRACT

It is possible to obtain a semiconductor device with an element isolation structure showing a good isolation characteristic by filing an interior of a minute trench with a good quality insulating film free of a defect such as a void, and a manufacturing method therefor. The semiconductor device includes a semiconductor substrate and an isolation insulator. A trench is formed on a main surface of the semiconductor substrate. The isolation insulator is formed in an interior of the trench using a thermal oxidation method to isolate element forming regions from each other on the main surface of the semiconductor substrate. The isolation insulator is a lamination body formed by a plurality of oxide film layers.

### BACKGROUND OF THE INVENTION

1. Field of the Invention

The present invention relates to a semiconductor device and a manufacturing method therefor, and more particularly to a semiconductor device capable of suppressing generation of a defect such as a void in an insulating film and a manufacturing method therefor.

2. Description of the Background Art

In a semiconductor device represented by a semiconductor memory device or the like, there have been conventionally formed an element forming region for forming a circuit element such as a field effect transistor or the like and an element isolation structure for isolating element forming regions from each other on a main surface of a semiconductor substrate. A structure called STI (Shallow Trench Isolation) is available as one of element isolation structures. FIGS. 36 to 39 are schematic sectional views for describing a formation method for the STI in a conventional semiconductor device. Description will be given of a manufacturing method for the STI in a conventional semiconductor device with reference to FIGS. 36 to 39.

At first, on a main surface of a semiconductor substrate 101 (see FIG. 36), a silicon oxide film 115 (see FIG. 36) is formed according to a thermal oxidation method. On silicon oxide film 115, a silicon nitride film 116 (see FIG. 36) is formed using a low pressure chemical vapor deposition method (LPCVD method) or the like. On silicon nitride film 116, a resist film (not shown) having a pattern is formed using a photolithographic method. With the resist film having a pattern as a mask, trenches 117a to 117c (see FIG. 36) are formed using common anisotropic etching. In such a way, a structure as shown in FIG. 36 is obtained.

Then, as shown in FIG. 37, a silicon oxide film 150 is formed that extends from the interiors of trenches 117a to 117c over onto the top surface of silicon nitride film 116. As a formation method for silicon oxide film 150, an LPCVD method using tetraethoxy silane (TEOS), for example, can be applied.

Then, portions of silicon oxide film 150 located above silicon nitride film 116 is removed using a photolithographic method or dry etching (anisotropic etching). Thereafter, the top surface of silicon oxide film 150 is planarized using a chemical mechanical polishing method (CMP method). As a result of the polishing, as shown in FIG. 38, a structure is obtained that the interiors of trenches 117a to 117c are filled with silicon oxide film 150a to 150c.

Then, silicon nitride film 116 (see FIG. 38) and silicon oxide film 115 (see FIG. 38) are removed by means of an etching method or the like. As a result of the removal, as shown in FIG. 39, a structure can be obtained that silicon oxide film 150a to 150c serving as STI is placed in the interiors of trenches 117a to 117c on the main surface of semiconductor substrate 101. Circuit elements such as field effect transistors are formed on element forming regions isolated by silicon oxide film 150a to 150c serving as respective element isolation structures (STI).

A request for miniaturization and high integration of a semiconductor device to higher levels is now increasingly intensified. Along with progress in miniaturization of a semiconductor device, an element isolation structure described above is also required to be reduced in size. In order to reduce a STI structure as shown in FIGS. 36 to 39 in size, a necessity arises for not only forming trenches 117a to 117c (see FIG. 37) each of a width narrower than in a conventional practice, but also filling trenches 117a to 117c each of a width narrower than in a prior practice with silicon oxide film 150 (see FIG. 37). While, in a step shown in FIG. 37, a LPCVD method using TEOS was used in forming silicon oxide film 150, when widths of trenches 117a to 117c became narrowed, there arose a case where a void 151 is formed in silicon oxide film 150 in the interiors of trenches 117a to 117c as shown in FIG. 40.

This is caused because of poor step coverage of silicon oxide film 150 formed by an LPCVD method using TEOS described above. That is, in a case where silicon oxide film 150 is formed in the interiors of trenches 117a to 117c by means of an LPCVD method using TEOS, a film growth speed of silicon oxide film 150 at the upper sections of trenches 117a to 117c is faster than at the bottom portions of trenches 117a to 117c. Therefore, in the upper sections of trenches 117a and 117c, portions of silicon oxide film 150 grown on the sidewall facing each other of each of trenches 117a and 117c are put into contact with each other earlier than the other parts (in other words, the upper sections of trenches 117a and 117c are caused into a blocked state). In this situation, since a film growth speed of silicon oxide film 150 at the bottom portions of trenches 117a and 117c is relatively smaller as described above, voids 151 are formed in respective trenches 117a and 117c when the upper sections of trenches 117a and 117c, as shown in FIG. 40, is blocked by silicon oxide 150. Herein, FIG. 40 is a schematic sectional view for describing a problem of a conventional semiconductor device, showing a state where the voids are formed in silicon oxide film 150 formed according to the LPCVD method.

Although whether or not a void 151 is formed is dependent on a process condition for a LPCVD method, it was found as a result of a study on formation of a void conducted by the inventor of the present invention that when widths (isolation width) of trenches 117a and 117c are smaller than 0.2 μm, a probability of forming a void as described above was higher. When such a void 151 was formed, there occurred a case of degradation of an isolation characteristic of a element isolation structure having, as a constituent, silicon oxide film 150 formed in the interior of trenches 117a to 117c.

As another method forming silicon oxide film 150 (see FIG. 37) in the interiors of trenches 117a and 117c of narrow widths, consideration is also given to use of a high density plasma chemical vapor deposition method (HDP-CVD method). In an HDP-CVD method, not only is a silicon oxide film formed in the interior of a trench, but, at the same time, the silicon oxide film is etched at the upper section of the trench. Therefore, since in the upper section of a trench, portions facing each other of a silicon oxide film formed on the sidewall of the trench have a reduced probability of being put into contact with each other earlier than in the other section, thereby enabling reduction in a risk that a void is formed in the interior of a trench.

Even in a case where an HDP-CVD method is adopted, however, an etching action is required to increase (an etching speed on etching silicon oxide film 150 (see FIG. 41) is increased in the upper section of trenches 117a to 117c (see FIG. 41)) in order to suppress the formation of a void as widths of trenches 117a to 117c (see FIG. 41) are narrowed. Consequently, in a case where silicon oxide film 150 (see FIG. 41) was formed using an HDP-CVD method, there arose a case where, as shown in FIG. 41, not only silicon oxide film 150 but also silicon nitride film 116, silicon oxide film 115 and further even semiconductor substrate 101 are etched on the upper portions of trenches 117a to 117c. FIG. 41 is a schematic sectional view for describing a problem of a conventional semiconductor device wherein there is shown a case where silicon oxide film 150 was formed using an HDP-CVD method.

In this case, scraped-off portions 152 are formed in the upper sections of respective trenches 117a to 117c on semiconductor substrate 101. In a case where such scraped-off portions 152 were formed, there arose a case of a poor isolation characteristic of the element isolation structures having silicon oxide film 150 as constituents formed in the interiors of respective trenches 117a to 117c. From a result of a study thereon by the inventor of the present invention, there was the lower limit of the order of 0.12 μm to widths of trenches 117a to 117c at which trenches 117a to 117c can be filled with silicon oxide film 150 while suppressing occurrence of scraped-off portions 152, which are described above.

In addition, silicon oxide film 150 (see FIGS. 40 and 41) formed using the above described LPCVD method or HDP-CVD method contains more of impurities in a silicon oxide film as compared with a silicon oxide film obtained according to a thermal oxidation (a method forming a silicon oxide film by oxidizing a silicon layer thermally) and what's worse, a chemical composition is unstable in many cases. Since a quality of a silicon oxide film obtained according to an LPCVD method or a HDP-CVD method is inferior to that of a silicon oxide film obtained with a thermal oxidation method, an isolation characteristic of an element isolation structure formed using the above described LPCVD method or the like was degraded. Such a degradation in isolation characteristic became more conspicuous with a reduced width of trench 117a to 117c.

### SUMMARY OF THE INVENTION

It is an object of the present invention to provide a semiconductor device with an element isolation structure showing a good isolation characteristic obtained by filling an interior of a minute trench with a good quality insulating film free of a defect such as a void, and a manufacturing method therefor.

A semiconductor device according to one aspect of the present invention includes a semiconductor substrate and an isolation insulator. A trench is formed on a main surface of the semiconductor substrate. The isolation insulator is formed in an interior of the trench using a thermal oxidation method to isolate element forming regions from each other on the main surface of the semiconductor substrate. The isolation insulator is a lamination body formed by a plurality of oxide film layers.

With such a structure adopted, as will be understood from a manufacturing method described later as well, an insulator according to the present invention can be obtained by repeating a process in which after formation of a film from which an oxide film layer is produced such as a silicon film with a film thickness sufficiently smaller than a width of a trench in the interior of the trench, and the film such as a silicon film is thermally oxidized. Since a film forming method excellent in step coverage can be used in formation of the silicon film or the like from which the oxide film layer described above is produced, a risk can be reduced that a defect such as a void is formed by blockage in an upper section of a trench.

A semiconductor device according to another aspect of the present invention includes a semiconductor substrate and an insulator. The semiconductor substrate has a main surface on which an unevenness portion is formed. The insulator is formed on the unevenness portion and made of a lamination body formed by a plurality of oxide film layers containing an n-type impurity element.

In this case, since an atom of impurity such as an alkali metal can be trapped by an n-type impurity element, suppression can be achieved of diffusion of the impurity atom in an oxide film layer. For this reason, suppression can be realized of degradation in characteristic of a semiconductor device due to an atom of impurity such as an alkali metal.

A manufacturing method for a semiconductor device according to still another aspect of the present invention includes a step of preparing a semiconductor substrate and a step of forming an insulator. In the step of preparing a semiconductor substrate, prepared is the semiconductor substrate having a main surface on which an unevenness portion is formed. In the step of forming an insulator, a step of forming a silicon film on the unevenness portion using a chemical vapor deposition method and a step of forming a silicon oxide film by oxidizing the silicon film are alternately repeated several times.

With such a method applied, a semiconductor device with an insulator according to the present invention can be obtained by repeating a process in which after formation of a silicon film from which an oxide film layer is produced such as a silicon film with a film thickness sufficiently smaller than a width of a recess of an unevenness portion in an interior of a trench and the film such as a silicon film is thermally oxidized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view showing a first embodiment of a semiconductor device according to the present invention;

FIGS. 2 and 3 are schematic sectional views for describing first and second steps in a manufacturing method for the semiconductor device shown in FIG. 1;

FIG. 4 is a schematic diagram of a semiconductor manufacturing apparatus used for forming an isolation insulator;

FIG. 5 is a flow chart showing a manufacturing method for a semiconductor device with an isolation insulator formed therein using the semiconductor manufacturing apparatus shown in FIG. 4;

FIG. 6 is a timing chart for describing process conditions in the semiconductor manufacturing apparatus shown in FIG. 4 upon forming an isolation insulator in accordance with the flow chart shown in FIG. 5;

FIGS. 7 to 13 are schematic sectional views for describing third to ninth steps in a manufacturing method for the semiconductor device shown in FIG. 1;

FIG. 14 is a schematic enlarged sectional view for describing an effect of the present invention;

FIG. 15 is a schematic enlarged sectional view for describing an effect of the present invention;

FIG. 16 is a schematic sectional view showing a second embodiment of a semiconductor device according to the present invention;

FIG. 17 is a schematic diagram showing a semiconductor manufacturing apparatus used in a manufacturing process for the semiconductor device shown in FIG. 16;

FIG. 18 is a flow chart showing a process in which an isolation insulator of the semiconductor device shown in FIG. 16 is formed using the film forming apparatus shown in FIG. 17;

FIG. 19 is a timing chart for describing operations in the film forming apparatus shown in FIG. 17 in formation of an isolation insulator using the film forming apparatus;

FIGS. 20 to 23 are schematic sectional views for describing first to fourth steps in a manufacturing method for the semiconductor device shown in FIG. 16;

FIG. 24 is a schematic enlarged sectional view showing a state where an oxide film is formed;

FIG. 25 is a flow chart for describing another example of a fabrication method for an isolation insulator in a manufacturing method for the semiconductor device shown in FIG. 16;

FIG. 26 is a timing chart for describing conditions for operations in the film forming apparatus shown in FIG. 17 in a case where the manufacturing method for an isolation insulator shown in FIG. 25 is performed in the film forming apparatus;

FIG. 27 is a schematic sectional view showing a third embodiment of a semiconductor device according to the present invention;

FIG. 28 is a flow chart for describing a process in which an isolation insulator of the semiconductor device shown in FIG. 27 is formed;

FIGS. 29 to 31 are schematic sectional views for describing first to third steps in a manufacturing method for the semiconductor device shown in FIG. 27;

FIG. 32 is a schematic sectional view showing an example modification of the third embodiment of a semiconductor device according to the present invention;

FIGS. 33 to 35 are schematic sectional views for describing first to third steps in a manufacturing method for the semiconductor device shown in FIG. 32;

FIGS. 36 to 39 are schematic sectional views for describing first to fourth steps in a formation method for an STI in a conventional semiconductor device;

FIG. 40 is a schematic sectional view for describing a problem in a conventional semiconductor device; and

FIG. 41 is a schematic sectional view for describing a problem in a conventional semiconductor device.

### DESCRIPTION OF THE PREFERRED EMBODIMENTS

Description will be given of embodiments of the present invention below on the basis of the accompanying drawings. Note that the same or corresponding constituents in the following drawings are attached by the same reference numbers and none of descriptions thereof is repeated.

First Embodiment

Description will be given of a first embodiment of a semiconductor device according to the present invention with reference to FIG. 1.

As shown in FIG. 1, a semiconductor device includes: isolation insulators 2a to 2c each formed so as to surround an element forming region on a main surface of a semiconductor substrate 1; a field effect transistor as a circuit element formed on the main surface of semiconductor substrate 1 in the element forming region isolated from other element forming regions by isolation insulators 2a to 2c each as an insulator; and interconnections 14a and 14b connected electrically to source/drain regions 8a and 8b of the field effect transistor. To be concrete, on the main surface of semiconductor substrate 1, isolation insulators 2a to 2c are formed so as to surround the element forming region as described above. Isolation insulators 2a, 2b and 2c each have a structure called a so-called STI (Shallow Trench Isolation).

Isolation insulator 2a is made of a lamination body constructed of oxide films 3a to 5a as a plurality of oxide film layers laminated in layers in a trench 17a formed on the main surface of semiconductor substrate 1. Oxide films 3a to 5a are formed so as to extend in a direction along the inner wall of trench 17a. That is, in the interior of trench 17a, oxide film 3a is formed so as to cover the sidewall and the bottom of trench 17a. On oxide film 3a, oxide film 4a is formed. On oxide film 4a, oxide film 5a is formed. In such a way, the interior of trench 17a is in a state to be filled with a lamination body constructed of oxide films 3a to 5a laminated in a plurality of layers.

Isolation insulator 2b is made of a lamination body constructed of oxide films 3b to 7b in oxide film layers placed so as to fill the interior of trench 17b formed on the main surface of semiconductor substrate 1. To be concrete, oxide film 3b is formed so as to cover the sidewall and bottom of trench 17b. On oxide film 3b, oxide film 4b is formed. On oxide film 4b, oxide film 5b is formed. On oxide film 5b, oxide film 6b is formed. On oxide film 6b, oxide film 7b is formed.

Furthermore, isolation insulator 2c as well is made of a lamination body constructed of oxide films 3c to 5c in oxide film layers placed so as to fill the interior of trench 17c formed on the main surface of semiconductor substrate 1. To be concrete, oxide film 3c is formed so as to cover the sidewall and bottom of trench 17c. On oxide film 3c, oxide film 4c is formed. On oxide film 4c, oxide film 5c is formed.

On an element forming region surrounded by isolation insulator 2a and 2b, a gate electrode 10 is placed on the main surface of semiconductor substrate 1 with a gate insulating film 9 interposed therebetween. Source/drain regions 8a and 8b are formed in the main surface of semiconductor substrate 1 so as to cause a channel region below gate insulating film 9 to be sandwiched therebetween. A field effect transistor is formed with gate electrode 10, gate insulating film 9 ad source/drain regions 8a and 8b.

An interlayer insulating film 11 is formed on the main surface of semiconductor substrate 1 so as to cover the above described field effect transistor. In interlayer insulating film 11, contact holes 12a and 12b are formed in regions located above source/drain regions 8a and 8b. The interiors of contact holes 12a and 12b are filled with respective conductor films 13a and 13b. Interconnections 14a and 14b are placed on the top interlayer insulating film 11 in regions located above respective conductor film 13a and 13b. Furthermore, on the top surface of interlayer insulating film 11, other interconnections 14c to 14e are placed. Interconnections 14a and 14b are connected electrically to respective source/drain regions 8a and 8b through conductor films 13a and 13b.

With such a structure adopted, as will be understood from a manufacturing method described later as well, isolation insulators 2a to 2c according to the present invention can be obtained by repeating a process in which after formation of a polycrystalline silicon film with a film thickness sufficiently smaller than a width of trenches 17a to 17c in the interiors of trenches 17a to 17c, the polycrystalline silicon film is thermally oxidized. Since a film forming method excellent in step coverage can be used in formation of the polycrystalline silicon film, a risk can be reduced that a defect such as a void is formed by blockage in the upper section of trenches 17a to 17c.

Furthermore, since a quality of oxide films 3a to 3c, 4a to 4c, 5a to 5c, 6b and 7b formed using a thermal oxidation method is more excellent than that of an oxide film formed using an LPCVD method or an HDP-CVD method, there can be realized isolation insulators 2a to 2c each having a good isolation characteristic.

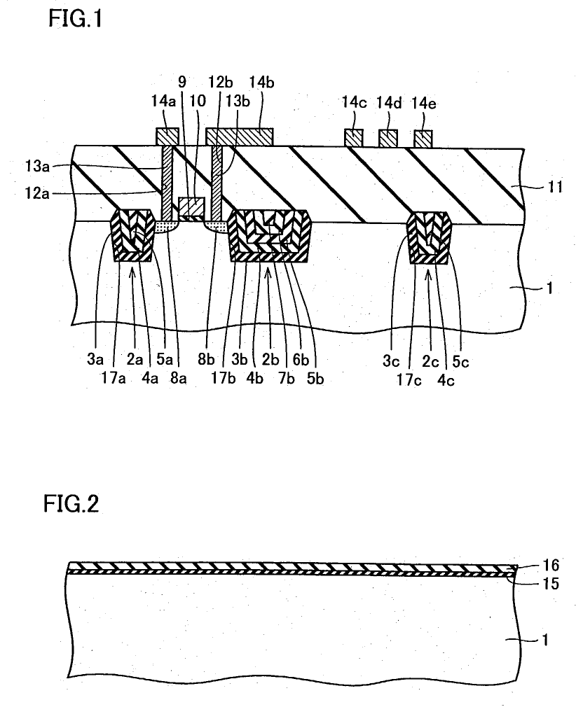

Then, description will be given of a manufacturing method for the semiconductor device shown in FIG. 1 with reference to FIGS. 2 to 13.

At first, thin silicon oxide film 15 (see FIG. 2) is formed on the main surface of semiconductor substrate 1 (see FIG. 2) according to a thermal oxidation method. Then, silicon nitride film 16 (see FIG. 2) is formed using a film forming method such as a low pressure chemical vapor deposition method (hereinafter referred to as an LPCVD method) or the like. In such a way, a structure as shown in FIG. 2 is obtained.

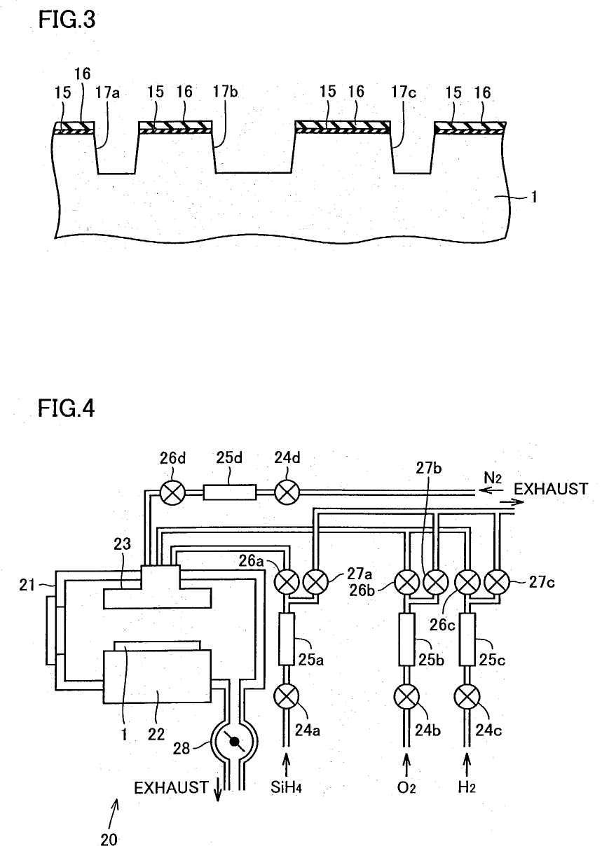

Then, a step is performed in which trenches 17a to 17c (see FIG. 3) are formed in regions where isolation insulators 2a to 2c (see FIG. 1) of semiconductor substrate 1 using a photolithographic method and etching. By performing steps of preparing a semiconductor substrate, a structure as shown in FIG. 3 is obtained.

Then, oxide films 3a to 3c, 4a to 4c, 5a to 5c, 6b and 7b (see FIG. 1) of which isolation insulators 2a to 2c are constructed are formed using a semiconductor manufacturing apparatus as shown in FIG. 4. Brief description will be given of the construction of the semiconductor manufacturing apparatus shown in FIG. 4 below.

As shown in FIG. 4, film forming apparatus 20, which is the semiconductor manufacturing apparatus, includes: a reaction chamber 21, a gas head 23 arranged in the interior of reaction chamber 21; a heater 22 placed at a site facing gas head 23 in the interior of reaction chamber 21; and a reaction gas feed mechanism for feeding a reaction gas into the interior of reaction chamber 21 through gas head 23. The reaction gas feed mechanism includes: a plurality of pipes connected to gas head 23 as shown in FIG. 4; valves 24a to 24d, 26a to 26d and 27a to 27c; and mass flow controllers 25a to 25d, provided in the plurality of pipes, and for controlling feed rates, the start and the stop of respective reaction gases. Mass flow controllers 25a to 25d are used for controlling flow rates of monosilane gas (SiH₄ gas), oxygen gas (O₂ gas), hydrogen gas (H₂ gas) and nitrogen gas (N₂ gas), respectively.

Furthermore, an exhaust pipe for discharging an atmosphere gas from the interior of reaction chamber 21 is connected to reaction chamber 21. A pressure control valve 28 is provided in the exhaust pipe. Note that heater 22 described above also exerts a function as a substrate holder for placing semiconductor substrate 1 to be treated on a surface thereof.

Then, brief description will be given of a method for forming isolation insulators 2a to 2c (see FIG. 1) using the apparatus shown in FIG. 4 on the basis of a flow chart shown in FIG. 5.

In a method for forming isolation insulators 2a to 2c (see FIG. 1), as shown in FIG. 5, a step (S110) of forming a trench on a main surface of a semiconductor substrate is at first performed as a step of preparing the semiconductor substrate having a main surface on which an unevenness portion is formed. This corresponds to a step shown in FIG. 3. Then, performed is a step (S120) of forming a polycrystalline silicon film. To be concrete, the polycrystalline silicon film is formed on the main surface of semiconductor substrate 1 on which trenches are formed so as to extend from the interior of the trench over onto the main surface of semiconductor substrate 1 suing a CVD method. Then, performed is an oxidation step (S130) of oxidizing the polycrystalline silicon film formed in the above step. In the oxidation step (S130), oxidation is performed till all the polycrystalline silicon film formed in the above step (S120) is oxidized into a silicon oxide film.

Then, performed is a step (S140) of determining whether or not filling of the trenches has been completed with a silicon oxide film formed in the oxidation step (S130). If filling of the trench has not been completed, the step (S120) of forming a polycrystalline silicon film and the oxidation step (S130) are again repeated. As a result of the repetition, performed is an insulator forming process including repetition of a pair of the step (S120) of forming a polycrystalline silicon film and the oxidation step (S130), thereby forming silicon oxide films in layers in the interiors of the trenches. In the step (S140) of determining whether or not filling of the trenches has been completed, if it is determined that filling of the trenches has been completed, performed is a post-processing step (S150) of performing a post-processing such as a step of removing a silicon oxide film in excess located on the main surface of a semiconductor substrate. In such a way, a process of forming isolation insulators 2a to 2c is completed. Note that in the step (S140) of determining whether or not filling of the trenches has been completed, an operation may be performed in which the number of repetitions of a pair of the step (S120) of forming a polycrystalline silicon film and the oxidation step (S130) is determined in advance from a relationship between a film thickness of an oxide film formed and a width of the trenches and verification is performed with a control device or the like on whether or not the above process of the pair has been repeated determined times of the number of repetitions, or detection is performed in real time on a state of portions in which the trenches of a semiconductor substrate are formed, thereby performing the above determination.

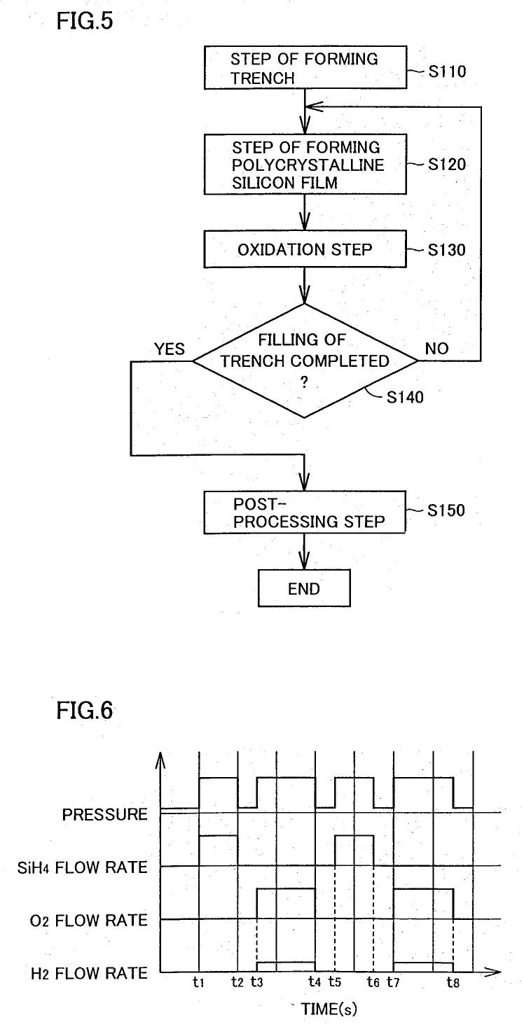

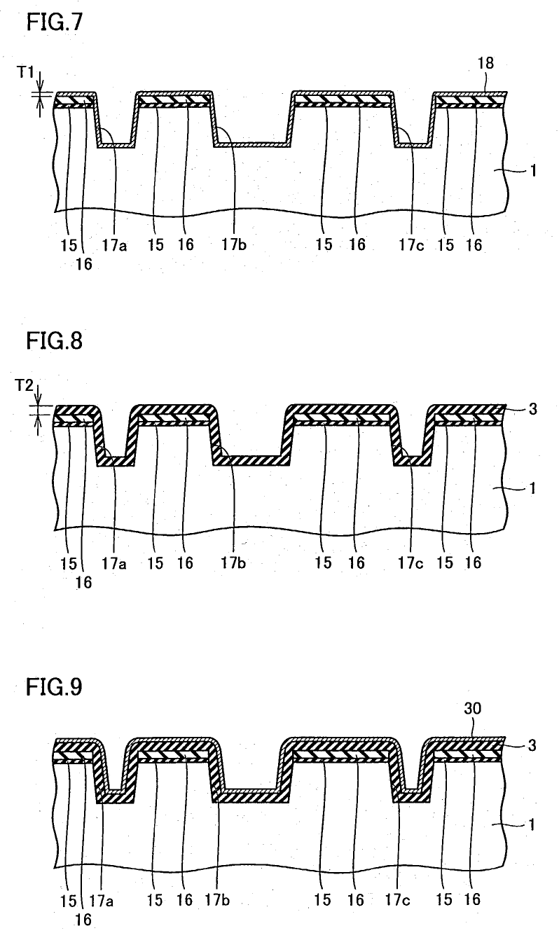

Then, description will be given of a manufacturing method for isolation insulators 2a to 2c in a manufacturing method for the semiconductor device shown in FIG. 1 with reference to a timing chart shown in FIG. 6 and schematic sectional views shown in FIGS. 7 to 13. In the timing chart of FIG. 6, the ordinate shows a pressure in the interior of reaction chamber 21 (see FIG. 4), flow rates of monosilane gas, oxygen gas, hydrogen gas and others. The abscissa shows time.

At first, as shown in FIG. 3, semiconductor substrate 1 on which trenches 17a to 17c are formed is placed on heater 22 in the interior of reaction chamber 21 of film forming apparatus 20 shown in FIG. 4. Then, the interior of reactor chamber 21 is evacuated to be in a vacuum state or filled with an inert gas atmosphere such as nitrogen. In a case where nitrogen gas is used as an inert gas, for example, not only are valves 24d and 26d caused to be in open state, but a flow rate of nitrogen gas (N₂ gas) is controlled with mass flow controller 25d. Furthermore, at this time, a pressure in the interior of reaction chamber 21 is kept at a prescribed value by controlling pressure control valve 28. Thereafter, a temperature of semiconductor substrate 1 is held at a value of the order of 620° C. by heater 22. Note that a temperature of semiconductor substrate 1 is preferably set from equal to or more than 520 to equal to or less than 750° C.

Then, at time point t₁ of FIG. 6, not only are valves 24a and 26a of film forming apparatus 20 shown in FIG. 4 caused to be in open state, but mass flow controller 25a is also controlled, thereby feeding monosilane gas (SiH₄) at a prescribed rate into the interior of reaction chamber 21 through gas head 23. As for a feed rate of monosilane, a value can be set at 0.05 L/min (50 sccm), for example. Note that a pressure in the interior of reaction chamber 21 at this time is kept at a value of the order of 30 Pa by controlling pressure control valve 28. Such a state is continued till time point t₂ of FIG. 6.

At this time, polycrystalline silicon film 18 (see FIG. 7) is formed on the surface of semiconductor substrate 1 at a growth speed of 0.3 nm/sec. At a time point t₂ (see FIG. 6) when a film thickness T1 (see FIG. 7) of polycrystalline silicon film 18 (see FIG. 7) reaches a value of the order of approximately 2 nm, valves 24a and 26a (see FIG. 4) are caused to be in dosed state, and valve 27a (see FIG. 4) is caused to be in open state. As a result of the operation, introduction of monosilane gas into the interior of reaction chamber 21 (see FIG. 4) is ceased. Thereafter, monosilane gas in the interior of reaction chamber 21 (see FIG. 4) is discharged from the exhaust port to thereby cause the interior of reaction chamber 21 to be in vacuum state. Note that a state under a sufficiently low pressure (for example, a pressure is equal to or less than 13.3 Pa) herein is called a vacuum state. In such a way, the structure as shown in FIG. 7 is obtained. Note that a step of forming polycrystalline silicon film 18 from monosilane gas as described above corresponds to the step (S120) of forming a polycrystalline silicon film shown in FIG. 5.

Then, in film forming apparatus 20 shown in FIG. 4, valves 24b, 24c, 26b and 26c are caused to be in open state and mass flow controllers 25b and 25c are controlled to thereby introduce oxygen (O₂) gas and hydrogen (H₂) gas to the interior of reaction chamber 21 at respective prescribed flow rate. At this time, a flow rate ratio of oxygen gas to hydrogen gas is set to 3:1 (O₂:H₂=3:1) in a mixed gas of oxygen gas and hydrogen gas introduced into the interior of reaction chamber 21. Note that a volumetric percentage of hydrogen gas in the mixed gas of oxygen gas and hydrogen gas (a proportion of a flow rate of hydrogen gas relative to a flow rate of oxygen gas) is preferably from equal to or more than 1% to equal to or less than 30%, both limits included. More preferably, a volumetric percentage of hydrogen gas in the mixed gas of oxygen gas and hydrogen gas is set from equal to or more than 1% to equal to or less than 20%. Further more preferably, a volumetric percentage of hydrogen gas in the mixed gas of oxygen gas and hydrogen gas is set from equal to or more than 1% to equal to or less than 10%. Under such conditions applied, polycrystalline silicon film 18 can be certainly oxidized.

A pressure in the interior of reaction chamber 21 (see FIG. 4) increases as shown in FIG. 6 by introducing oxygen gas and hydrogen gas into the interior of reaction chamber 21 (see FIG. 4) from a time point t₃ (see FIG. 6) when oxygen gas and hydrogen gas begin to be introduced into the interior of reaction chamber 21 in such a way. Note that in FIG. 6, the pressure means a pressure in the interior of reaction chamber 21 (see FIG. 4) and the SH₄ flow rate, O₂ flow rate and H₂ flow rate means feed flow rates of SH₄ gas, O₂ gas and H₂ gas, respectively. Polycrystalline silicon film 18 shown in FIG. 7 is oxidized in a state where the interior of reaction chamber 21 (see FIG. 4) is replaced to a mixed gas atmosphere of oxygen gas and hydrogen gas to be transformed into oxide film 3 (silicon oxide film) as shown in FIG. 8. Note that a pressure in the interior of reaction chamber 21 (see FIG. 4) at this time can be set in the range of 666 to 2666 Pa (5 to 50 Torr).

Such an oxidation process is continued till almost all of polycrystalline silicon film 18 shown in FIG. 7 is oxidized. In the above conditions, it takes about 10 sec to oxidize polycrystalline silicon film 18 (see FIG. 7) to the full. A film thickness T2 (see FIG. 8) of oxide film 3 (see FIG. 8) to be formed is on the order of 3 nm. By doing so, oxide film 3 can be formed that extends from the interiors of trenches 17a to 17c of semiconductor substrate 1 over onto silicon nitride film 16.

At time point t₄ (see FIG. 6) after a time point at which formation of oxide film 3 is completed, feed of oxygen gas and hydrogen gas into reaction chamber 21 (see FIG. 4) is ceased. To be concrete, in film forming apparatus 20 shown in FIG. 4, valves 24b, 24c, 26b and 26c are caused to be in closed state, and valves 27b and 27c are caused to be in open state. The atmosphere gas in the interior of reaction chamber 21 is discharged from the exhaust port to thereby evacuate the interior of reaction chamber 21 to be in vacuum state.

Then, as apparently from FIG. 8 as well, since the interiors of trenches 17a to 17c are not perfectly filled with oxide film 3, a pair of the step (S120) of forming a polycrystalline silicon film and the oxidation step (S130) shown in FIG. 5 is again repeated. To be concrete, at time point T₅ of FIG. 6, monosilane gas is introduced into the interior of reaction chamber 21 of film forming apparatus 20 shown in FIG. 4 by an operation similar to the operation at time point t₁. As a result, polycrystalline silicon film 30 (see FIG. 9) is formed on oxide film 3. After the step of forming polycrystalline silicon film 30 (see FIG. 9) is continued till time point t₆ (see FIG. 6), not only is feed of monosilane gas into the interior of reaction chamber 21 (see FIG. 4) ceased by an operation similar to the operation at time point t₂ of FIG. 6, but the atmosphere gas in the interior of reaction chamber 21 is also discharged. By doing so, a structure as shown in FIG. 9 is obtained.

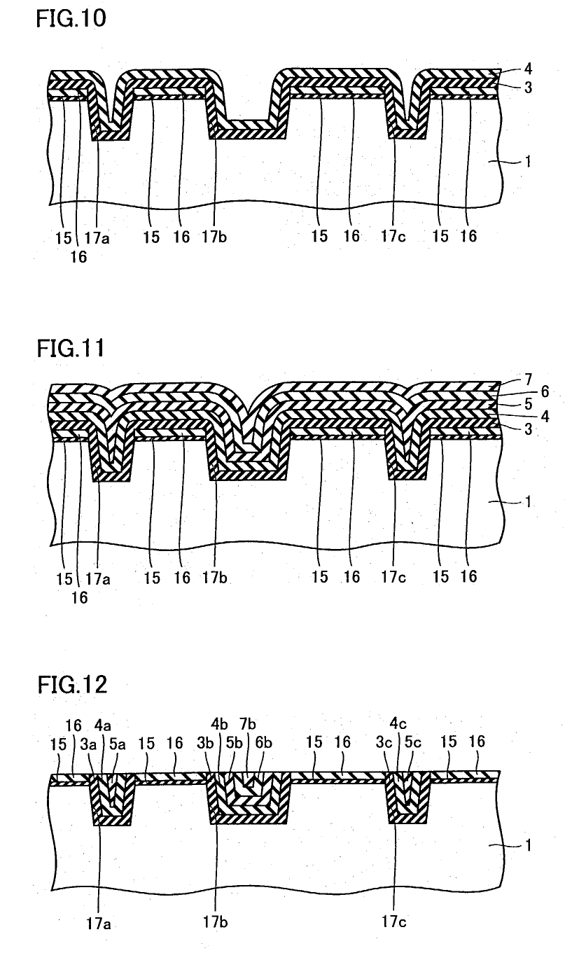

Then, at time point t₇ of FIG. 6, oxygen gas and hydrogen gas are introduced into the interior of reaction chamber 21 (see FIG. 4) by an operation similar to the operation at time point t₃. As a result, polycrystalline silicon film 30 (see FIG. 9) is oxidized. Such an oxidation step is continued till time point t₈ (see FIG. 6). By doing so, oxide film 4, as shown in FIG. 10, can be formed on oxide film 3. Thereafter, at time point t₈, feed of oxygen gas and hydrogen gas into the interior of chamber 21 is ceased by an operation similar to the operation at time point t₄. As a result, a structure as shown in FIG. 10 can be obtained.

A pair of the step (S120) of forming a polycrystalline silicon film and the oxidation step (S130) (see FIG. 5) is repeated in such a way till all of trenches 17a to 17c are thereby filled with laminated bodies each constructed of oxide films 3 to 7 (silicon oxide films) as shown in FIG. 1. As a result, a structure as shown in FIG. 11 can be obtained. In order to form oxide films 3 to 7 shown in FIG. 11, a pair of the step (S120) of forming a polycrystalline silicon film and the oxidation step (S130) (see FIG. 5) herein are repeated 5 times. By repeating pair of the step (S120) of forming a polycrystalline silicon film and the oxidation step (S130) (see FIG. 5), the interiors of trenches 17a to 17c, as shown in FIG. 1, can be filled with oxide films 3 to 7 without voids or the like.

After trenches 17a to 17c, as shown in FIG. 11, are perfectly filled with laminated bodies constructed of oxide films 3 to 7, oxide films 3 to 7 located above silicon nitride 16, as shown in FIG. 12, are removed using a photolithographic method and dry etching. Thereafter, the top surfaces of the laminated bodies constructed of oxide films 3 to 7 are planarized using a chemical mechanical polishing method (CMP method). As a result, a structure as shown in FIG. 12 is obtained.

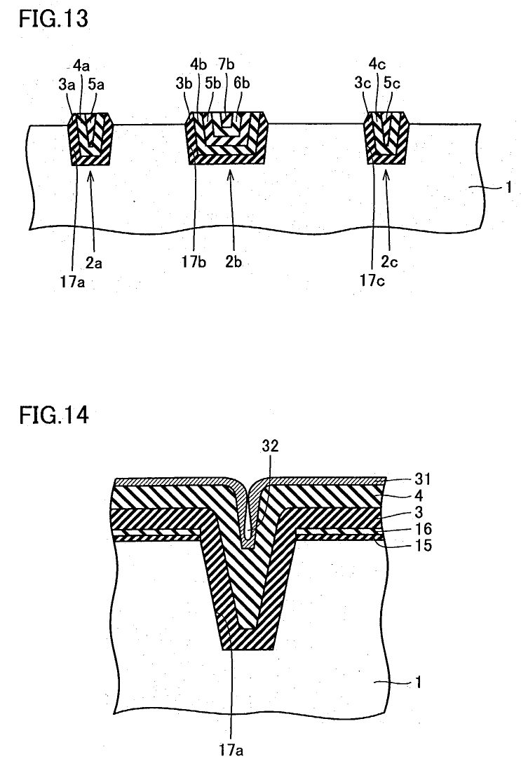

Then, silicon nitride film 16 and silicon oxide film 15 are removed from the main surface of semiconductor substrate 1. As a result, a structure as shown in FIG. 13 is obtained. Steps shown in FIGS. 12 and 13 correspond to the post-processing step (S150) of FIG. 5. By doing so, isolation insulators 2a to 2c can be obtained.

After the step shown in FIG. 13, formed according to a method similar to a conventional practice is a field effect transistor including: gate insulating film 9 (see FIG. 1); gate electrode 10 (see FIG. 1); and source/drain regions 8a and 8b (see FIG. 1). Furthermore, interlayer insulating film 11 (see FIG. 1) is formed so as to cover the field effect transistor. Contact holes 12a and 12b (see FIG. 1) are formed in interlayer insulating film 11 at sites located above source/drain regions 8a and 8b. Conductor films 13a and 13b (see FIG. 1) are formed in the interiors of contact holes 12a and 12b. Interconnections 14a and 14b (see FIG. 1) are formed in regions located above conductor film 13a and 13b. Other interconnections 14c and 14e (see FIG. 1) are simultaneously formed on the top surface of interlayer insulating film 11. By performing such a way, a semiconductor device as shown in FIG. 1 can be obtained.

According to knowledge having been acquired by the inventor of the present invention, it has been found that in the step of forming polycrystalline silicon film 18 or 30 (the step of forming a polycrystalline film) shown in respective FIGS. 7 and 9, polycrystalline silicon film 18 or 30 (see FIGS. 7 and 9) formed using the above described process conditions is more excellent in step coverage than an oxide film formed using an LPCVD method with TEOS or the like. Further, polycrystalline silicon film 18 or 30 (see FIGS. 7 and 9) formed in this way was oxidized by thermal oxidation in an atmosphere containing oxygen and hydrogen, thereby having enabled a high purity oxide films 3 and 4 (see FIGS. 8 and 10) containing no impurities therein. Furthermore, since polycrystalline silicon film 18 or 30 (see FIGS. 7 and 9) with a film thickness sufficiently smaller than a with of trenches 17a to 17c is formed for formation of oxide films 3 and 4, followed by thermal oxidation thereof, formation of a void can be suppressed dissimilarly to a case where trenches 17a to 17c is filled with an oxide film in a single operation.

Note that, a method is known in which simultaneously feeding monosilane gas and an oxidative gas such as oxygen into reaction chamber 21 (see FIG. 4) to form a silicon oxide film. However, in a case where monosilane gas and an oxidative gas are simultaneously fed into a reaction chamber to form a silicon oxide film, a reaction between monosilane gas and the oxidative gas is a supply rate determining step for a reaction gas to the surface of semiconductor substrate 1. For this reason, an oxide film formed by simultaneous introduction of monosialne gas and oxidative gas into a reaction chamber is short of step coverage. Furthermore, in a case of simultaneous introduction of monosialne gas and oxidative gas into a reaction chamber as described above, a problem also arises since foreign matter formed by a reaction in a gas phase between monosilane gas and oxidative gas is mixed into an oxide film formed. For this reason, in a formation method for a oxide film in which monosilane gas and oxidative gas are simultaneously fed, it is difficult to obtain an oxide film including almost no impurity (therefore of high purity) while suppressing occurrence of a defect such as a void, which can be obtained with the present invention.

Furthermore, a CVD method has also been known in which different kinds of gases are alternatively fed into reaction chamber 21 (see FIG. 4). However, the effect that the interiors of trenches 17a to 17c (see FIG. 1) with a relative narrow width can be filled with an oxide film in a state where occurrence of a void is suppressed is realized by a great influence of selection of monosilane gas as a gas for forming a polycrystalline silicon film and in addition thereto, selection of a mixed gas composed of oxygen as an oxidative gas and hydrogen gas, both done by the inventor of the present invention. That is, since polycrystalline silicon films 18 and 30 (see FIGS. 7 and 9) formed using monosilane gas have extremely excellent step coverage, polycrystalline silicon films 18 and 30 can be formed so as to certainly cover the sidewalls and the bottoms of trenches 17a to 17c each with a relatively narrow width.

Furthermore, in a case where after a pair of the step (S120) of forming a polycrystalline silicon film and the oxidation step (S130) (see FIG. 5) is repeated several times, there is a chance that a fine void 32 is produced even if monosialne gas is used when a polycrystalline silicon film 31 is formed in the interior of a trench with an extremely narrow width. FIG. 14 shows a state where polycrystalline silicon film 31 is formed on oxide film 4 after oxide films 3 and 4 are formed in trench 17a.

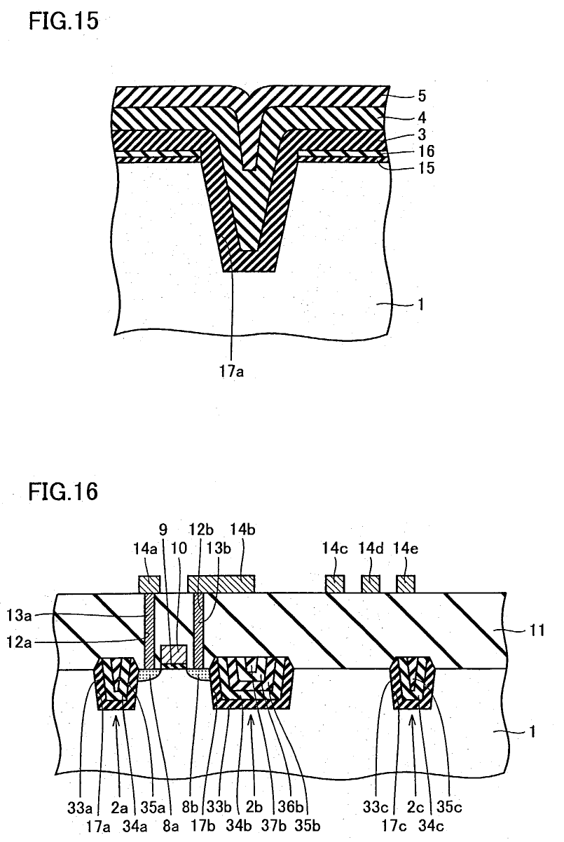

As shown in FIG. 14, after blockage occurs with polycrystalline silicon film 31 in the upper section of a trench with a narrow width formed on the top surface of oxide film 4 above trench 17a, it is hard to fill a void 32 with a common CVD method. In the present invention, however, polycrystalline silicon film 31 formed is oxidized using a mixed gas of oxygen gas and hydrogen gas after the formation of polycrystalline silicon film 31. Therefore, an oxidative species caused by a mixed gas of oxygen gas and hydrogen gas described above penetrates into the interior of polycrystalline silicon film 31 or an oxide film (insulating film) formed by oxidation of polycrystalline silicon film 31 up to a polycrystalline silicon film portion forming a wall surface of a void 32. Then, since a volumetric expansion occurs in oxidation of polycrystalline silicon film 31 (transformed into a silicon oxide film), a void 32 (see FIG. 14) is shrunk or disappears by the volumetric expansion. As a result, as shown in FIG. 15, a void free oxide film 5 can be formed. Such an effect can be realized for the first time by adopting a method in which a pair of a step of forming a polycrystalline silicon film and a step of oxidizing the polycrystalline silicon film, as in the present invention, is repeatedly performed as an individual independent step.

Note that since when a film thickness T1 (see FIG. 7) of a polycrystalline silicon film formed at a time is thinner, a size of a void 32 formed also becomes smaller or occurrence of a void can be suppressed, a void can more certainly become extinct in an oxidation step. When a film thickness of polycrystalline silicon film 18 or 30 (see FIGS. 8 and 9) is however excessively thin, a thickness of an oxide film formed at a time is also thin. For this reason, a case can cross a mind where the number of repetitive cycles of a pair of the step (S120) of forming a polycrystalline silicon film and the oxidation step (S130) (see FIG. 5) for filling the interiors of trenches 17a to 17c increases, which reduces a manufacturing efficiency to the contrary. Therefore, an extremely thin film thickness of a polycrystalline silicon film 18 or 30 formed (see FIGS. 7 and 9) is thought not to be so much practical. According to a result from a study conducted by the inventor of the present invention, occurrence of a void was able to be suppressed as far as a film thickness of a polycrystalline silicon film 18 or 30 (see FIGS. 7 and 9) formed at one time was equal to or less than 5 nm, though the film thickness was dependent on a tilt angle of the sidewall portions of trenches 17a to 17c.

Naturally, a film thickness of polycrystalline silicon film 18 or 30 formed in the step (S120) of forming a polycrystalline silicon film (see FIG. 5) and film thickness values of oxide films 3 and 4 (see FIGS. 8 and 10) are not limited to the values in the above described embodiment Furthermore, film forming conditions for polycrystalline silicon films 18 and 30 and a flow rate ratio between oxygen and hydrogen in the oxidation step are also not limited to the values in the above described embodiment.

A time (a time between time point t₁ and time point t₂ (see FIG. 6)) during which monosilane gas is fed into the interior of reaction chamber 21 (see FIG. 4) is not limited to the conditions of the above described embodiment but the time may be changed in each step of forming a polycrystalline silicon film to be transformed to oxide film 3 to 7 (see FIG. 1).

Second Embodiment

Description will be given of a second embodiment of a semiconductor device according to the present invention with reference to FIG. 16.

The semiconductor device, as shown in FIG. 16, has a structure fundamentally similar to the semiconductor device shown in FIG. 1 except that phosphorus, which is an n-type impurity, is contained in oxide films 33a to 33c, 34a to 34c, 35a to 35c, 36b and 37b of which respective isolation insulators 2a to 2c are constructed. As is apparent from a manufacturing method described later, in isolation insulators 2a to 2c, a phosphorus concentration contained in oxide films 33a to 33c, 34a to 34c, 35a to 35c, 36b and 37b increases in a direction from oxide films 33a to 33c located in the lowest layer (a region closest to semiconductor substrate 1) to oxide films 35a to 35c or oxide film 37b in the uppermost layer.

With such a change in the phosphorus concentration, not only is an effect similar to the semiconductor device according to the present invention shown in FIG. 1 obtained but there also formed regions containing phosphorus layerwise in respective isolation insulators 2a to 2c. Phosphorus contained in isolation insulators 2a to 2c traps atoms of impurities such as an alkali metal exerting an adverse influence on operations in a semiconductor device. Therefore, there arises an effect to suppress diffusion of atoms of impurities such as an alkali metal into a semiconductor substrate. Consequently, occurrence of a problem is suppressed that a characteristic of a semiconductor device is degraded by the presence of atoms of impurities such as an alkali metal.

Furthermore, since phosphorus is not uniformly distributed in isolation insulators 2a to 2c but different in concentration according to each oxide film among oxide films 33a to 33c, 34a to 34c, 35a to 35c, 36b and 37b, isolation insulators 2a to 2c each have a laminated structure in layers having different phosphorus concentrations according to each layer (phosphorus atoms are distributed in a layerwise concentrated manner). Therefore, the effect can be enhanced that traps atoms of impurities such as a alkali metal, which is described above.

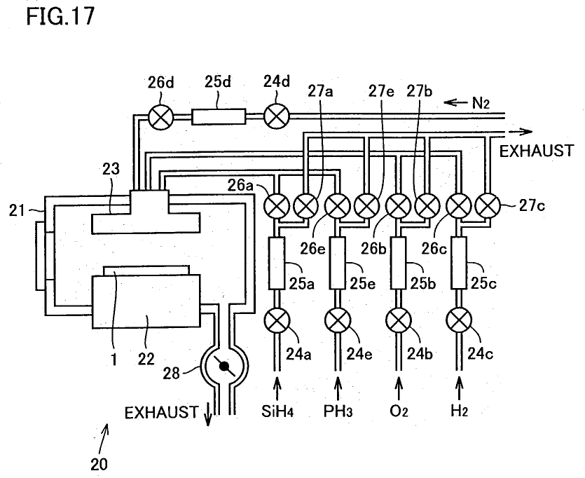

Then, in FIG. 17, there is shown a semiconductor manufacturing apparatus used in a manufacturing process for a semiconductor device shown in FIG. 16.

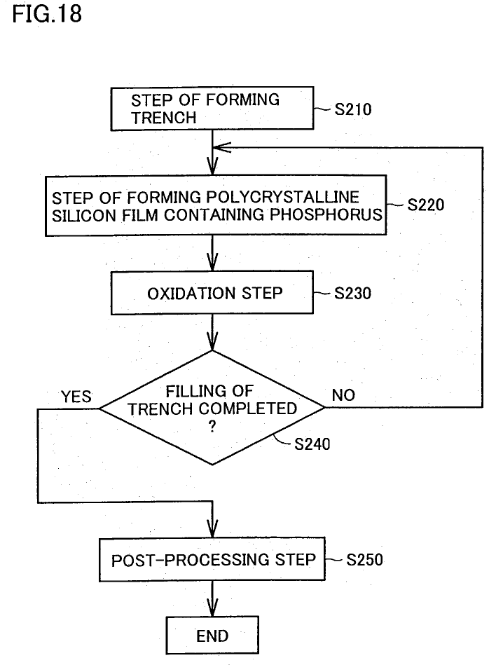

Film forming apparatus 20 as a semiconductor manufacturing apparatus shown in FIG. 17 is an apparatus for use in formation of isolation insulators 2a to 2c of a semiconductor device shown in FIG. 16 and of a construction fundamentally similar to film forming apparatus 20 shown in FIG. 4. Film forming apparatus 20 shown in FIG. 17 includes: a pipe channel for feeding phosphine (PH₃) into the interior of reaction chamber 21; valves 24e, 26e and 27e; and a mass flow controller 25e in a reaction gas feed mechanism. Brief description will be given of a process forming isolation insulators 2a to 2c of a semiconductor device shown in FIG. 16 using film forming apparatus 20 shown in FIG. 17 with reference to FIG. 18.

As shown in FIG. 18, the process forming isolation insulators 2a to 2c shown in FIG. 16 is fundamentally similar to the process (the process shown in FIG. 5) forming isolation insulators in the first embodiment of the present invention except that a step (S220) of forming a polycrystalline silicon film containing phosphorus (see FIG. 18) is implemented instead of the step (S120) of forming a polycrystalline silicon film shown in FIG. 5. The other steps are fundamentally similar to those in the flow chart shown in FIG. 5.

To be concrete, a step (S210) of forming a trench of FIG. 18 corresponds to the step (S110) forming a trench of FIG. 5. Furthermore, an oxidation step (S230) of FIG. 18 corresponds to the oxidation step (S130) of FIG. 5. A step (S240) of determining whether or not filling of the trench of FIG. 18 has been completed corresponds to the step (S140) of determining whether or not filling of the trench of FIG. 5 has been completed. A post-processing step (S250) of FIG. 18 corresponds to the post-processing step (S150) of FIG. 5.

Then, description will be given of a manufacturing method for the semiconductor device shown in FIG. 16.

At first, steps similar to the steps shown in FIGS. 2 and 3 are performed to thereby form trenches 17a to 17c (see FIG. 20) on a main surface of semiconductor substrate 1 (see FIG. 20). Then, similar to the manufacturing method for the semiconductor device in the first embodiment of the present invention, semiconductor substrate 1 is placed on heater 22 (see FIG. 17) in reaction chamber 21 (see FIG. 17) of film forming apparatus 20 (see FIG. 17) to heat semiconductor substrate 1 to a prescribed temperature.

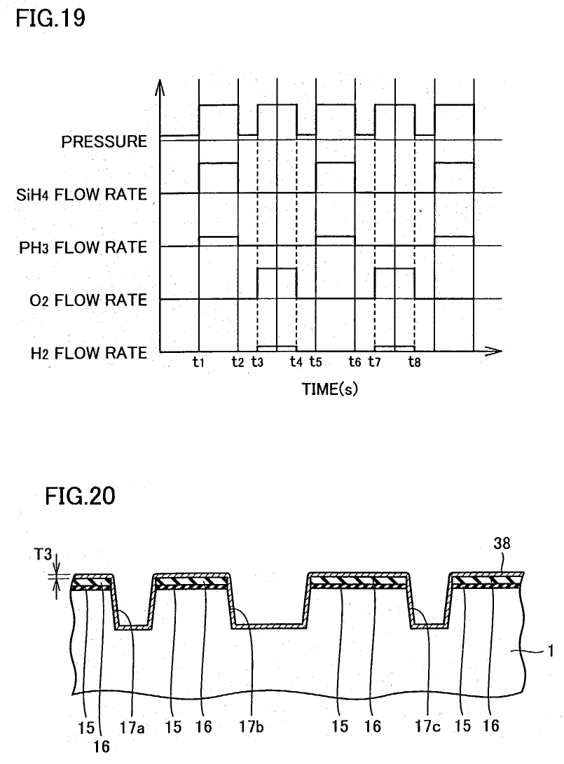

At time point t₁ of FIG. 19, not only are valves 24a, 24e, 26a and 26e of film forming apparatus 20 shown in FIG. 17 caused to be in open state, but monosilane gas and phosphine gas (PH₃) are also introduced into the interior of reaction chamber 21 at respective prescribed flow rates by controlling mass flow controllers 25a and 25e. As a flow rate of monosilane gas, herein, a value can be set to 0.05 L/min (50 sccm). Phosphine gas as a gas containing an n-type impurity element is mixed with nitrogen to be diluted to a phosphine concentration of 1%. The diluted gas is fed into reaction chamber 21 at a flow rate of 0.01 L/min (10 sccm). As a result, as shown in FIG. 20, there can be easily formed a polycrystalline silicon film 38 containing phosphorus of a film thickness T3 extending from the interiors of trenches 17a to 17c over onto the top surface of silicon nitride film 16 as shown in FIG. 20 by means of a CVD method.

Note that a pressure in reaction chamber 21 at this time can be set to 30 Pa similarly to the first embodiment. Furthermore, a heating temperature of semiconductor substrate 1 can be set to 620° C. At time point t₂ in FIG. 19, when a prescribed time elapses in this state, not only are valves 24a, 24e, 26a and 26e of film forming apparatus 20 shown in FIG. 17 caused to be in closed state, but valves 27a and 27e are also caused to be in open state to thereby cease a feed of monosilane gas and phosphine gas into the interior of reaction chamber 21. In such a way, the step (S220) of forming a polycrystalline silicon film containing phophorus can be performed (see FIG. 18).

Then, an atmosphere gas is discharged from the interior of reaction chamber 21 to thereby evacuate the interior of reaction chamber to be in an almost vacuum state. Thereafter, oxygen gas and hydrogen gas are fed into the interior of reaction chamber 21 of film forming apparatus 20 shown in FIG. 17 starting at time point t₃ of FIG. 19 onwards. To be concrete, in film forming apparatus 20 shown in FIG. 17, not only are valves 24b, 24c, 26b and 26c caused to be in open state, but oxygen gas and hydrogen gas are also fed into the interior of reaction chamber 21 at respective flow rates by controlling mass flow controllers 25b and 25c.

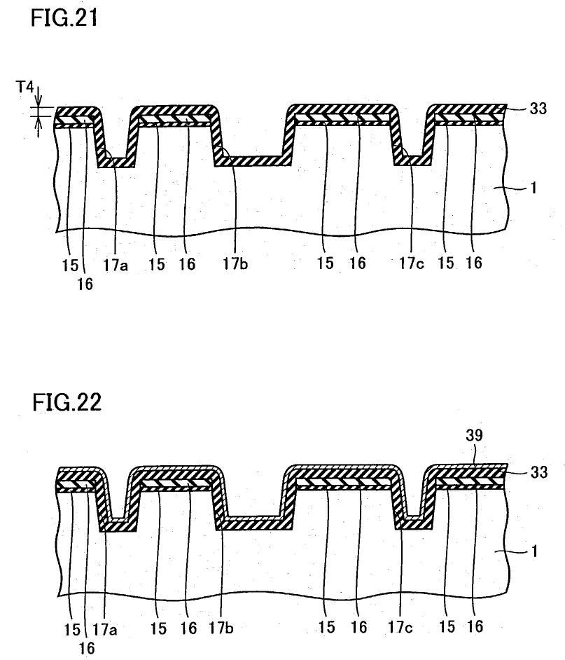

Feed rates of oxygen gas and hydrogen gas are fundamentally similar to those of oxygen gas and hydrogen gas in the oxidation step of the manufacturing method for the semiconductor device in the first embodiment of the present invention. As a result of a feed of the gases, oxidation occurs of polycrystalline silicon film 38 (see FIG. 20) containing phosphorus formed on the surface of semiconductor substrate 1 (see FIG. 20). The oxidation step is continued till almost all of polycrystalline silicon film 38 is oxidized. At time point t₄ (see FIG. 19), when the oxidation of polycrystalline silicon film 38 (see FIG. 20) ends, not only are valves 24b, 24c, 26b and 26c of film forming apparatus 20 shown in FIG. 17 caused to be in closed state, but valves 27b and 27c are also caused to be in open state to thereby cease a feed of oxygen gas and hydrogen gas to reaction chamber 21. By doing so, the oxidation step (S230) (see FIG. 18) ends. In the oxidation step (S230), polycrystalline silicon film 38 (see FIG. 20) containing phosphorus is oxidized to become oxide film 33 (see FIG. 21) of a film thickness T4 containing phosphorus. Thereby, a structure as shown in FIG. 21 is obtained.

Note that, since polycrystalline silicon film 38 (see FIG. 20) contains phosphorus, there can be obtained an effect to accelerate oxidation in the oxidation step (S230) (see FIG. 18). Accordingly, a time of the oxidation step (S230) (see FIG. 18) of oxidizing a polycrystalline silicon film in the second embodiment described above of the present invention can be shorter than that of the oxidation step (S130) (see FIG. 5) in the first embodiment. Note that such an effect to accelerate oxidation can also be obtained by adding an n-type impurity (for example arsenic) other than phosphorus into polycrystalline silicon film 38 (see FIG. 20).

Then, at time point t₅ of FIG. 19, monosilane gas and phosphine gas are introduced into reaction chamber 21 of film forming apparatus 20 shown in FIG. 17 similarly to the operation at time point t₁ to thereby perform the step (S220) (see FIG. 18) of forming polycrystalline film 39 (see FIG. 22) containing phosphorus. By continuing such a film forming process till time point t₆ (see FIG. 19), a structure as shown in FIG. 22 can be obtained.

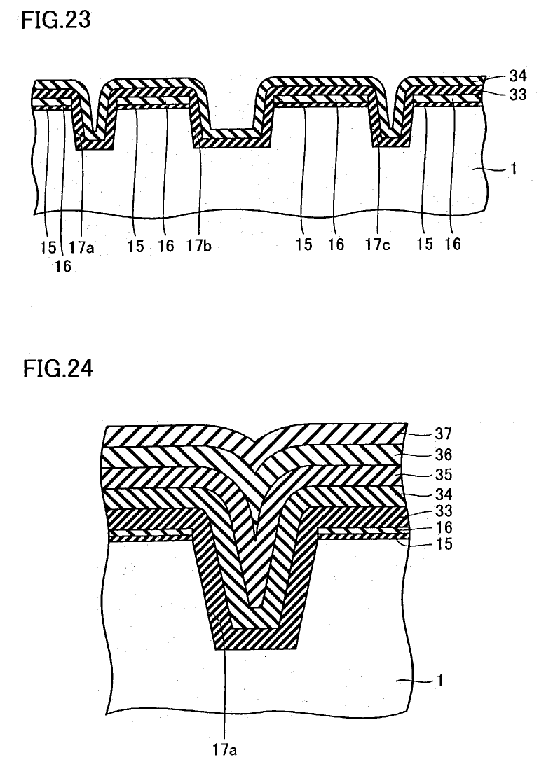

At time point t₆ of FIG. 19, an operation similar to the operation performed at time point t₂ is performed to cease a feed of monosilane gas and phosphine gas into reaction chamber 21. Thereafter, reaction chamber 21 is evacuated to be in a vacuum state, followed by an operation similar to the operation at time point t₃, at time point t₉ of FIG. 19. To be concrete, in film forming apparatus 20 shown in FIG. 17, valves 24b, 24c, 26b and 26c and others are operated to feed oxygen gas and hydrogen gas as an oxidative gas into the interior of reaction chamber 21 similarly to the operation at time point t₃ (see FIG. 19). By doing so, the oxidation step (S230) (see FIG. 18) is implemented. Conditions at this time of feed rates of oxygen gas and hydrogen gas, a heating temperature of semiconductor substrate 1 and others are set to be similar to those in the oxidation step described in FIG. 21. As a result of the oxidation step applied, polycrystalline silicon film 39 (see FIG. 22) containing phosphorus can be oxidized. The oxidation step is continued till all of polycrystalline silicon film 39 containing phosphorus is perfectly oxidized. Thereafter, at time point t₈ shown in FIG. 19, an operation similar to the operation at time point t₄ is performed to thereby cease a feed of oxygen gas and hydrogen gas into reaction chamber 21 of film forming apparatus 20 shown in FIG. 17. As a result of a series of the above steps, oxide film 34 containing phosphorus as shown in FIG. 23 can be formed.

Hereinafter, the step (S220) (see FIG. 18) described above of forming a polycrystalline silicon film containing phosphorus and the oxidation step (S230) (see FIG. 18) are repeated to fill trenches 17a to 17c with oxide films containing phosphorus. Thereby, a structure similar to that shown in FIG. 11 can be obtained. Thereafter, performed is a process (including a step corresponding to the post-processing step (S250) (see FIG. 18) and a step of forming a field effect transistor) similar to the process described in FIGS. 12 and 13, thereby enabling the semiconductor device shown in FIG. 16 to be obtained.

In the process of filling the interiors of trenches 17a to 17c with oxide films 33 to 36 (see FIG. 24) for forming isolation insulators 2a to 2c, a pair of the step (S220) (see FIG. 18) of forming a polycrystalline silicon film containing phosphorus and the oxidation step (S230) (see FIG. 18) of oxidizing the polycrystalline silicon film formed is repeated to form a lamination body constructed of oxide films 33 to 36 containing phosphorus as shown in FIG. 24. Phosphorus contained in the polycrystalline silicon film migrates in the polycrystalline silicon film and oxide films during the oxidation step due to a difference in segregation coefficient between the oxide films (silicon oxide films) and the polycrystalline silicon film. Eventually, a phosphorus concentration in oxide film 37 located in the uppermost layer shows the highest value with the lowest phosphorus concentration in oxide film 33 located in the lowest layer. As a result of such a distributional change in phosphorus concentration, a phosphorus concentration gradually increases from oxide film 33 toward oxide film 37 (a phosphorus concentration in oxide film 36 as one oxide film layer is higher than that in oxide films 35 to 33 as other oxide film layers disposed at positions closer to semiconductor substrate 1 than one oxide film 36).

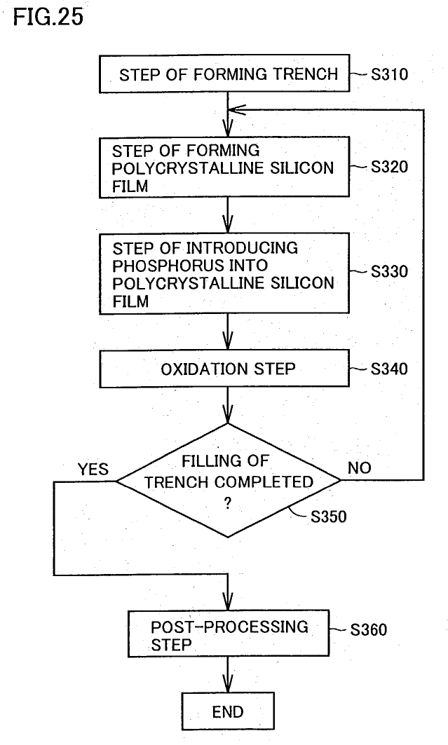

Note that film forming conditions for polycrystalline silicon films 38 and 39 containing phosphorus are not limited to the above described conditions, but other conditions may be adopted. For example, a process may be allowed in which a polycrystalline silicon film containing no phosphorus is formed in a similar manner to the first embodiment of the present invention, followed by a step of introducing phosphorus into the polycrystalline silicon film. To be concrete, an isolation insulator may be formed according to a process as shown in FIG. 25. Description will be given of another example of the manufacturing method for isolation insulators 2a to 2c with reference to FIG. 25.

The manufacturing method for an isolation insulator shown in FIG. 25 is fundamentally similar to the manufacturing method shown in FIG. 18 except that performed are a step (S320) of forming a polycrystalline silicon film and a step (S330) of introducing phosphorus into a polycrystalline silicon film instead of the step (S220) of forming a polycrystalline silicon film containing phosphorus in FIG. 18. The other steps are similar to corresponding steps in the manufacturing method shown in FIG. 18.

To be concrete, a step (S310) forming a trench of FIG. 25 corresponds to the step (S210) of forming a trench of FIG. 18. Furthermore, an oxidation step (S340) and a step (S350) of determining whether or not filling of the trench has been completed of FIG. 25 correspond to the oxidation step (S230) and the step (S240), respectively, of FIG. 18 of determining whether or not filling of the trench has been completed. Furthermore, a post-processing step (S360) of FIG. 25 corresponds to the post-processing step (S250) of FIG. 18. Even with such a process applied, isolation insulators 2a to 2c of the semiconductor device shown in FIG. 16 can be obtained.

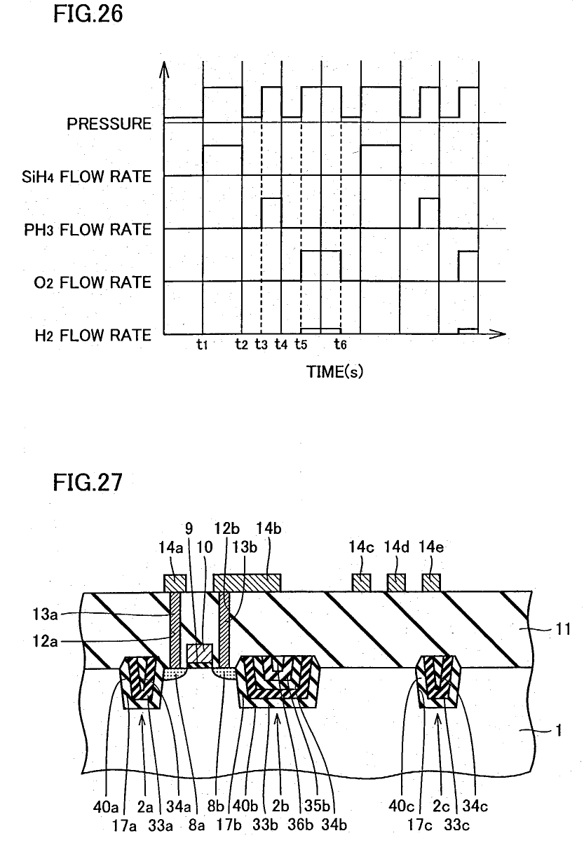

Brief description will be given of a concrete process in a case where the manufacturing method for isolation insulators shown in FIG. 25 with reference to FIG. 26.

At first, after steps (the step (S310) forming a trench) (see FIG. 25) similar to the steps shown in FIGS. 2 and 3 are performed, semiconductor substrate 1 (see FIG. 17) is placed in the interior of reaction chamber 21 of film forming apparatus 20 (see FIG. 17). Then, at time point t₁ of FIG. 26, monosialne gas is fed into reaction chamber 21 of film forming chamber 20 shown in FIG. 17. To be concrete, valves 24a and 26a of film forming apparatus 20 shown in FIG. 17 are placed in open state to feed monosilane gas at a prescribed rate into reaction chamber 21 using mass flow controller 25a. Thereby, a polycrystalline silicon film containing no phosphorus can be formed so as to extend from the interiors of trenches 17a to 17c on semiconductor substrate 1 over onto silicon nitride film 16 (see FIG. 20). In such a way, performed is the step (S320) (see FIG. 25) of forming a polycrystalline silicon film. As a result, a structure similar to the structure shown in FIG. 7 can be obtained. Thereafter, at time point t₂ of FIG. 26, a feed of monosilane gas into reaction chamber 21 (see FIG. 17) is ceased. To be detailed, not only are valves 24a and 26a in film forming apparatus 20 of FIG. 17 caused to be in closed state, but valve 27a is also caused to be in open state. Then an atmosphere gas in reaction chamber 21 (see FIG. 17) is discharged.

Then, at time point t₃ of FIG. 26, valves 24e and 26e of film forming apparatus 20 shown in FIG. 17 is caused to be in open state to thereby feed phosphine gas into reaction chamber 21. The phosphine gas has been diluted with nitrogen gas as described above to a concentration of 1%. Since, by introducing phosphine gas as an atmosphere gas in such a way, the phosphine gas can be caused to contact the polycrystalline silicon film formed previously, phosphorus can be introduced into the polycrystalline silicon film. By doing so, performed is the step (S330) (see FIG. 25) of introducing phosphorus into a polycrystalline silicon film. Then, at time point t₄ of FIG. 26, not only are valves 24e and 26e in film forming apparatus 20 of FIG. 17 caused to be in closed state, but also valve 27e is also caused to be in open state. Thereby, a feed of phosphine gas into reaction chamber 21 is ceased. Thereafter, an atmosphere gas in reaction chamber 21 (see FIG. 17) is discharged.

Then, at time point t₅ of FIG. 26, an operation similar to the operation at time point t₃ in FIG. 19 is performed to thereby feed hydrogen gas and oxygen gas into reaction chamber. 21 of film forming apparatus 20 shown in FIG. 17. As a result of a feed of the gases, the polycrystalline silicon film containing phosphorus is oxidized. At time point t₆, when a prescribed time elapses, an operation similar to the operation at time point t₄ in FIG. 19 is performed to thereby cease a feed of hydrogen gas and oxygen gas into reaction chamber 21 of film forming apparatus 20 shown in FIG. 17. In such a way, the oxidation step (S340) (see FIG. 25) is completed.

A set of the step (S320) of forming a polycrystalline silicon film and the step (S330) of introducing phosphorus into the polycrystalline silicon film and the oxidation step (S340) (see FIG. 25) are repeated to thereby make it possible to fill trenches 17a to 17c (see FIG. 16) with oxide films laminated in layers. Thereafter, performed are the steps shown in FIGS. 12 and 13, that is the post-processing step (S360) (see FIG. 25), thereby enabling formation of isolation insulators 2a to 2c shown in FIG. 16. In addition, a semiconductor device 1 shown in FIG. 16 can be obtained by performing a step of forming a field effect transistor on the main surface of semiconductor substrate 1 (see FIG. 16).

By performing the step (S320) of forming a polycrystalline silicon film and the step (S330) of introducing phosphorus into the polycrystalline silicon film (see FIG. 25) separately, certain suppression of occurrence of a void or the like defect can be achieved in the interiors of trenches 17a to 17c. This is because step coverage of a polycrystalline silicon film formed in the step (S320) of forming the polycrystalline silicon film is more excellent than in the step of forming a polycrystalline silicon film containing phosphorus formed in a single step such as the step shown in FIG. 18. Note that in a case where phosphorus is introduced into a polycrystalline silicon film formed previously, a quantity of phosphorus to be introduced is smaller than in a case where a diluted phosphine gas and monosilane gas described above are simultaneously fed into reaction chamber 21 (see FIG. 17), but an effect to accelerate oxidation, which improves an oxidation speed in oxidation of polycrystalline silicon film, can be sufficiently achieved.

Third Embodiment

Description will be given of a third embodiment of a semiconductor device according to the present invention with reference to FIG. 27.

The semiconductor device, as shown in FIG. 27, has a structure fundamentally similar to the semiconductor device shown in FIG. 1 except a structure of isolation insulators 2a to 2c. That is, in the semiconductor device shown in FIG. 27, in a laminated structures of oxide films 40a to 40c, 33a to 33c, 34a to 34c, 35b and 36b of which isolation insulators 2a to 2c are constructed, oxide films 40a to 40c located in the lowest layer (regions closest semiconductor substrate 1) are base oxide films and formed according to a manufacturing method and with a film quality, different from that of the other oxide films in upper layers.

To be concrete, in the semiconductor device shown in FIG. 27, silicon oxide films 40a to 40c in the lowest layer are silicon oxide films formed according to an LPCVD method. Oxide films containing phosphorus 33a to 33c, 34a to 34c, 35b and 36b located in the upper layers of silicon oxide films 40a to 40c as barrier layers are formed in a method fundamentally similar to that for oxide films 33a to 33c of which isolation insulators of a semiconductor device of the second embodiment are constructed with phosphorus contained in oxide films 33a to 33c.

In even such a semiconductor device, not only can an effect similar to that of the second embodiment of the present invention be achieved, but diffusion of phosphorus into the bulk of semiconductor substrate 1 can also be suppressed since oxide films 40a to 40c as barrier films serve as a barrier against diffusion of an impurity element (phosphorus) in isolation insulators 2a to 2c.

Furthermore, there is a case where a stress occurs in oxide films 33a to 33c, 34a to 34c, 35b and 36b in forming oxide films 33a to 33c, 34a to 34c, 35b and 36b as oxide film layers using a thermal oxidation method. In a semiconductor device shown in FIG. 27, however, since oxide films 40a to 40c each work as a relaxation layer for stresses in oxide films 33a to 33c, 34a to 34c, 35b and 36b, a risk can be reduced that the stresses are propagated in semiconductor substrate 1 to produce a cause for a defect in semiconductor substrate 1.

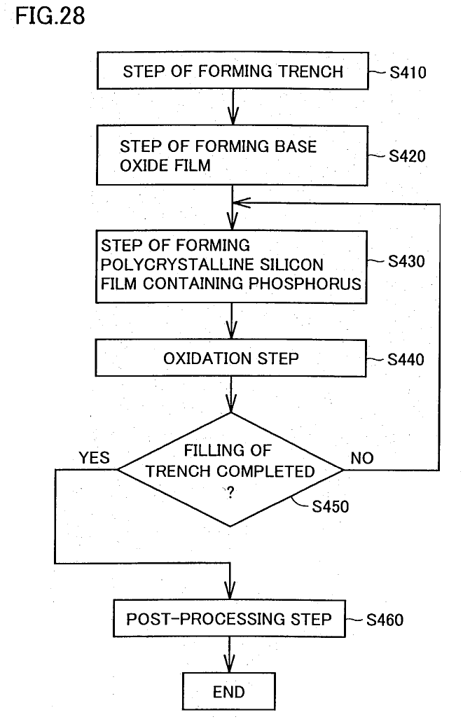

Brief description will be given of a manufacturing process for the semiconductor device shown in FIG. 27 with reference to FIGS. 28 to 31.

A manufacturing method for an isolation insulator shown in FIG. 28 is fundamentally similar to the manufacturing method for the semiconductor device of the first embodiment of the present invention except that a step (S420) of forming a base oxide film as a step of forming a barrier film is provided prior to a step (S430) of forming a polycrystalline silicon film. The other steps than the step (S420) of forming a base oxide film are fundamentally similar to the steps of forming an isolation insulator in a semiconductor device of the second embodiment of the present invention shown in FIG. 18.

That is, the step (S410) of forming a trench of FIG. 28 corresponds to the step (S210) of forming a trench of FIG. 18. Furthermore, the step (S430) of forming a polycrystalline silicon film containing phosphorus of FIG. 28, an oxidation step (S440), a step (S450) of determining whether or not filling of a trench has been completed and a post-processing step (S460) of FIG. 28 correspond to the step (S120) of forming a polycrystalline silicon film containing phosphorus, the step of forming a polycrystalline silicon film containing phosphorus, the oxidation step (S130), the step (S140) of determining whether or not filling of a trench has been completed and the post-processing step (S150), respectively, of FIG. 18.

Then, brief description will be given of a manufacturing method for the semiconductor device shown in FIG. 27.

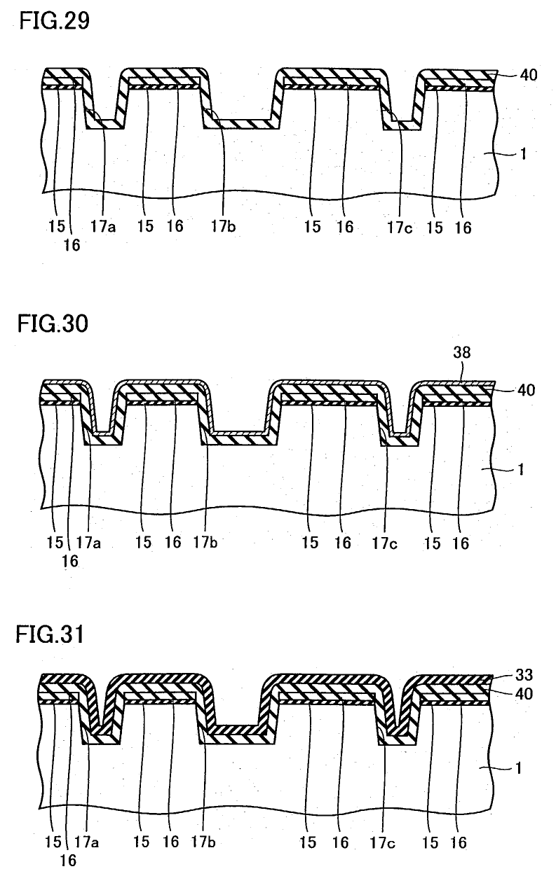

At first, the step (a step of forming a trench (S410)) (see FIG. 28) similar to the steps shown in FIGS. 2 and 3 is performed to thereby form trenches 17a to 17c (see FIG. 27) on the main surface of semiconductor substrate 1. Then, a silicon polycrystalline silicon film 40 (see FIG. 29) is firmed so as to extend from the interiors of trenches 17a to 17c over onto the top surface of silicon nitride film 16 (see FIG. 29) as the step (S420) of forming a base oxide film (see FIG. 28). By doing so, a structure as shown in FIG. 29 is obtained. Note that a thickness of silicon oxide film 40 can be set, for example, to 10 nm. Silicon oxide film 40 is formed using an LPCVD method.

By forming silicon oxide film 40 as a base oxide film, a stress produced by oxide film 33 (see FIG. 31) or the like formed on silicon oxide film 40 can be relaxed to suppress introduction of a defect into semiconductor substrate 1 by the stress. Furthermore, silicon oxide film 40 as a base oxide film has a function as a barrier preventing diffusion into semiconductor substrate 1 of phosphorus contained in oxide films 33a to 33c, 34a to 34c, 35b and 36b of which isolation insulators 2a to 2c are constructed. Note that a film thickness of silicon oxide film 40 is not limited to the value described above.

Then, as an a step corresponding to the step (S430) (see FIG. 28) of forming a polycrystalline silicon film containing phosphorus, polycrystalline silicon film 38 containing phosphorus is formed on silicon oxide film 40. A formation method for polycrystalline silicon film 38 is fundamentally similar to the step shown in FIG. 20 in the second embodiment of the present invention.

Then, as the oxidation step (S440) (see FIG. 28), performed is a step of forming oxide film 33 (see FIG. 31) by oxidation of polycrystalline silicon film 38 (see FIG. 30). As the oxidation step (S440), a step similar to the step described in FIG. 21 can be used. As a result of the above process, a structure as shown in FIG. 31 can be obtained.

Hereinafter, by performing steps similar to those described in FIGS. 22 and 23 and FIGS. 11 to 13, a semiconductor device shown in FIG. 27 having isolation insulators 2a to 2c can be obtained.

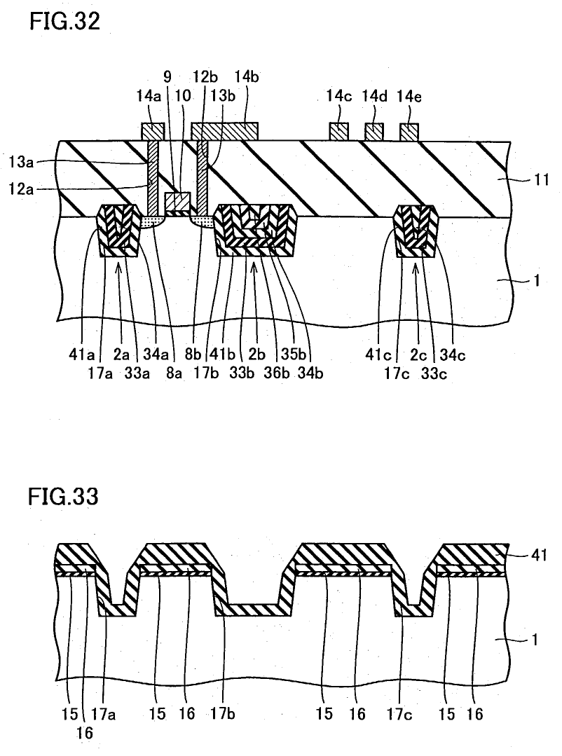

Description will be given of an example modification of the third embodiment according to the present invention with reference to FIG. 32.

A semiconductor device, as shown in FIG. 32, has a structure fundamentally similar to the semiconductor device shown in FIG. 27 except that silicon oxide films 41a to 41c as barrier films located in the lowest layer among oxide films of which isolation insulators 2a to 2c are constructed are formed by mean of a HDP-CVD method.

Description will be given of a manufacturing method for a semiconductor device shown in FIG. 32 with reference to FIGS. 33 to 35.

At first, steps similar to steps shown in FIGS. 2 and 3 are performed to thereby form trenches 17a to 17c (see FIG. 33) on the main surface of semiconductor substrate 1. Thereafter, silicon oxide film 41 (see FIG. 33) is formed using an HDP-CVD method. By doing so, a structure as shown in FIG. 33 is obtained.

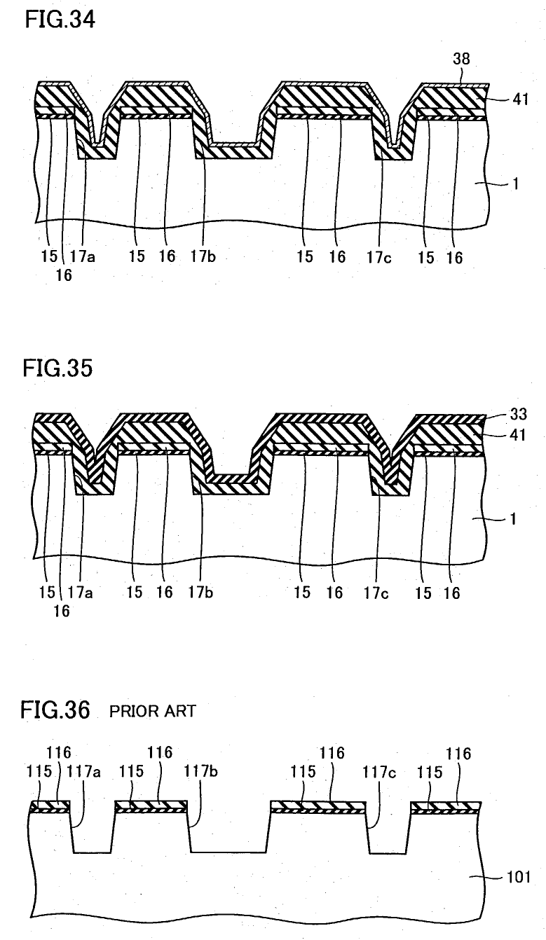

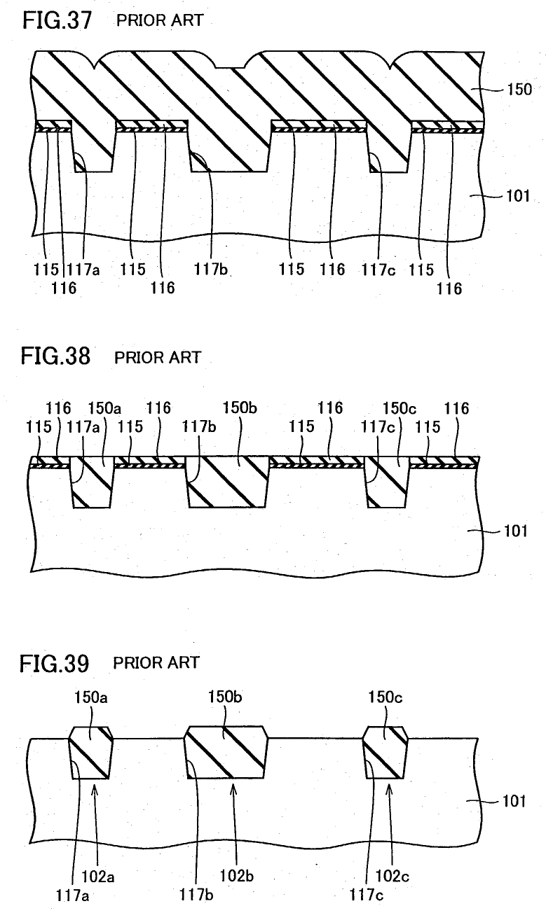

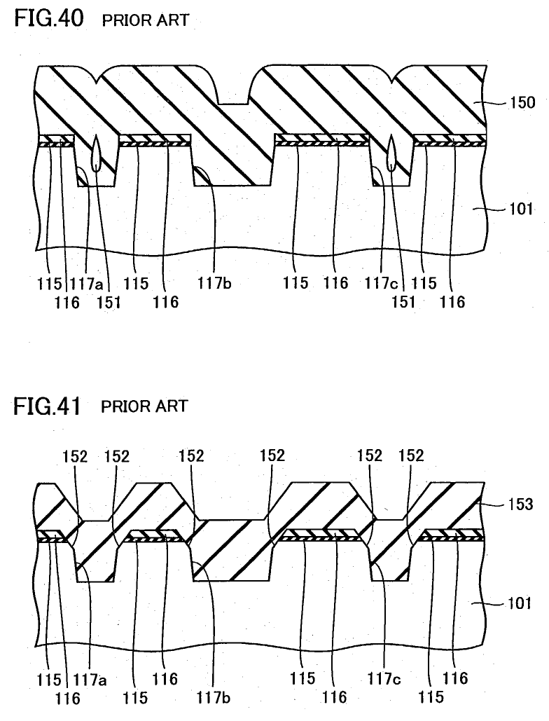

Then, similar to the step shown in FIG. 30, polycrystalline silicon film 38 (see FIG. 34) containing phosphorus is formed on silicon oxide film 41. Thereby, a structure as shown in FIG. 34 can be obtained.

Then, similar to the step shown in FIG. 31, polycrystalline silicon film 38 is oxidized to thereby form oxide film 33 (see FIG. 35) containing phosphorus. As a result of formation of the oxide film 33, a structure as shown in FIG. 35 is obtained.

Thereafter, similar to a manufacturing method for the semiconductor device shown in FIG. 27, formation of a polycrystalline silicon film and oxidation are repeated to fill the interiors of the trenches 17a ad 17c (see FIG. 32) with oxide films After steps corresponding to a post-processing step (S460) (see FIG. 28) shown in FIGS. 11 to 13 are performed, a field effect transistor and an interlayer insulating film 11 (see FIG. 32) or the like are formed, thereby enabling the semiconductor device shown in FIG. 32 to be obtained.

By forming an oxide film as a base oxide film according to an HDP-CVD and further repeating a pair of formation of a polycrystalline silicon film and oxidation thereof in the other portions in isolation insulators 2a to 2c (see FIG. 32) to thereby obtain laminated layers of oxides, a defect can be avoided that the surface of semiconductor substrate 1 is partially scraped off and problematic while trenches 17a to 17c (see FIG. 32) are filled only by means of the HDP-CVD method.

Moreover, in case where a different method as a formation method for an oxide film is combined as described above, for example in the step (S420) (see FIG. 28) of forming a base oxide film, an existing CVD technique with a relatively high speed in film formation can be applied. In doing so, a time can be shortened that is necessary for filling of trenches 17a to 17c (see FIG. 32).

Note that in a step of forming silicon oxide films 40a to 40c as base oxide films, any of film forming methods may be used.

As shown in the above described first to third embodiments, a semiconductor device according to a first aspect of the present invention includes: semiconductor substrate 1; and isolation insulators 2a to 2c. Trenches 17a to 17c are formed on the main surface of semiconductor substrate 1. Isolation insulators 2a to 2c are formed in the interiors of trenches 17a to 17c using a thermal oxidation method and isolate element 25 forming regions from each other on the main surface of semiconductor substrate 1. Isolation insulators 2a to 2c are laminated bodies constructed of a plurality of oxide film layers such as oxide films 3a to 3c. 4a to 4c, 5a to 5c, 6b and 7b.

With such a structure adopted, as will be understood from a manufacturing method described later as well, an insulator according to the present invention can be obtained by repeating a process in which after formation of a film from which an oxide film layer is produced such as a silicon film with a film thickness sufficiently smaller than a width of a trench in the interior of the trench, the film such as a silicon film is thermally oxidized. Since a film forming method excellent in step coverage can be used in formation of the silicon film or the like from which the oxide film layer described above is produced, a risk can be reduced that a defect such as a void is formed by blockage in an upper section of a trench.

Moreover, even if a void or the like is formed in the interior of a trench in forming a film from which an oxide film layer is produced, a portion facing the void can be oxidized since oxygen is supplied to the portion facing the void in the film by diffusion of oxygen in the film in thermal oxidation of the film. In oxidation of the film such as a silicon film, since a volume thereof expands, a void can be made extinct in progress of the volumetric expansion. As a result of the oxidation of a portion facing a void and the volumetric expansion, an insulator can be obtained without a defect such as a void.

Since a film quality of an oxide film layer formed using a thermal oxidation method is more excellent than that of an oxide film formed by use of an LPCVD method or an HDP-CVD method, an isolation insulator having an excellent isolation characteristic can be realized.

A semiconductor device according to the first aspect may further have barrier films, each being interposed between the inner wall of a trench and an isolation insulator, and such as silicon oxide film 40a to 40c, and 41a to 41c.

In this case, since a barrier film serves as a barrier against diffusion of impurity element and others contained in an isolation insulator, it can be suppressed that the impurity element and others contained in the isolation insulator diffuse into the interior of a semiconductor substrate.

There is a case where a stress is produced in oxide film layers when the oxide film layers of which an isolation insulator is constructed are formed using a thermal oxidation method. In the present invention, however, since a barrier film works as a relaxation film for the stress in the oxide layer films, the stress is propagated in a semiconductor substrate, thereby enabling a risk that the stress causes a defect in the semiconductor substrate to decrease.

In a semiconductor device as shown in FIG. 16 described above, according to the first aspect, oxide layer films such as oxide films 33c to 33c, 34a to 34c, 35a to 35c, 36b and 37b may contain an n-type impurity element.

In this case, since an impurity element such as an alkali metal can be trapped by an n-type impurity element, diffusion of an impurity element can be suppressed in oxide film layers. Therefore, suppression can be realized of degradation of an isolation characteristic of an isolation insulator due to an impurity element such as an alkali metal.

Furthermore, in a thermal oxidation step of forming oxide film layers, an oxidation speed in oxidation for forming the oxide film layers can be improved by incorporating an n-type impurity in a film from which an oxide film layer is formed. Therefore, reduction can be realized in time necessary for the thermal oxidation step for forming the oxide film layers.

Furthermore, like a semiconductor device shown in the second and third embodiments, a semiconductor device according to another aspect of the present invention has semiconductor substrate 1 and insulators 2a to 2c. Semiconductor substrate 1 has a main surface on which unevenness portions such as trenches 17a to 17c are formed. Insulator is formed on the unevenness portion and constructed of as a lamination body constructed of a plurality of oxide film layers containing an n-type impurity element.

In this case, since an impurity element such as an alkali metal can be trapped by an n-type impurity element, suppression can be realized of diffusion of an impurity atom in the oxide film layers. For this reason, suppression can be achieved of degradation of a characteristic of a semiconductor device caused by diffusion of an atom of an impurity such as an alkali metal in constituents of a semiconductor element such as a field effect transistor formed on a semiconductor substrate.

In a semiconductor device according to another aspect described above, the oxide film layers may be formed using a thermal oxidation method.

In this case, as can also be understood from a manufacturing method for the semiconductor device as well, isolation insulators according to the present invention can be obtained by repeating a process of thermal oxidation of a film such as a silicon film from which the oxide film layers are formed after formation of the film as a silicon film of a thickness sufficiently smaller than a width of a recess (for example, a trench) of an unevenness portion in the interior of the recess. Since, in formation of a silicon film from which the above described oxide film layers are formed a film forming method excellent in step coverage can be employed, a risk can be reduced that a defect such as a void is formed by blockage in the upper section.

Moreover, even if a void or the like is formed in the interior of a recess in forming a film from which the above described oxide film layers are formed, a portion facing the void can be oxidized since oxygen is supplied to the portion facing the void in the film by diffusion of oxygen in the film in thermal oxidation of the film. In oxidation of the film such as a silicon film, since a volume thereof expands, a void can be made extinct in progress of the volumetric expansion. As a result of the oxidation of a portion facing a void and the volumetric expansion, an insulator can be obtained without defect such as a void.

Since a film quality of an oxide film layer formed using a thermal oxidation method is more excellent than that of an oxide film formed by use of an LPCVD method or an HDP-CVD method, an isolation insulator having an excellent isolation characteristic can be realized. Therefore, if an insulator according to the present invention is used as an isolation insulator for isolating element forming regions, an isolation insulator with excellent isolation characteristic can be realized.

Furthermore, in a thermal oxidation step for forming oxide film layers, an oxidation speed in oxidation for forming the oxide film layers can be improved by incorporating an n-type impurity in a film from which the oxide film layers are formed. Therefore, reduction can be realized in time necessary for the thermal oxidation step for forming the oxide film layers.

In a semiconductor device according to another aspect described above, an unevenness portion may include a trench formed on a main surface of the semiconductor device. An insulator may be formed so as to fill a trench.

In this case, an insulator according to the present invention can be used as a trench isolating structure.

A semiconductor device according to another aspect described above may further have a barrier such as one of silicon oxide films 40a to 40c and 41a to 41c, interposed between the inner wall of the trench and an insulator.

In this case, since a barrier film works as a barrier against diffusion of an impurity element and others in an insulator, suppression can be realized of diffusion of an impurity element and others contained in an insulator into the interior of a semiconductor substrate.

There is a case where a stress is produced in oxide film layers when the oxide film layers of which an isolation insulator is constructed are formed using a thermal oxidation method. In the present invention, however, since a barrier film works as a relaxation film for the stress in the oxide layer films, the stress is propagated in a semiconductor substrate, thereby enabling a risk that the stress causes a defect in the semiconductor substrate to decrease.

In a semiconductor device according to the first aspect or another aspect, an n-type impurity element may be phosphorus.

In this case, in a thermal oxidation process for forming oxide layer films, not only can an oxidation speed be certainly improved, but an impurity atom such as an alkali metal can be trapped by phosphorus.

In a semiconductor device according to the first aspect or another aspect, a concentration of an n-type impurity element in one oxide film layer among a plurality of oxide film layers, as shown in the second embodiment described above, may be higher than a concentration of the n-type impurity element in another oxide film layer located closer to a semiconductor substrate than the one oxide film layer.

In such a way, since a concentration of an n-type impurity element increases nearer the uppermost oxide film layer, an impurity element such as an alkali metal can be more certainly trapped in an upper layer of the oxide film layers.

In a semiconductor device according to the first aspect or another aspect, a barrier film may be a silicon oxide film formed by means of one of a high density plasma chemical vapor deposition method or a low pressure chemical vapor deposition method. Furthermore, in a semiconductor device according to the first aspect or another aspect, oxide film layers may be obtained by thermal oxidation of silicon.

In this case, since, as a formation method for a barrier film filling a trench or a recess of a recess/projection, an HDP-CVD method and an LPCVD method are used, a conventional semiconductor manufacturing apparatus can be used in a manufacturing process for a semiconductor device according to the present invention. Furthermore, by using an HPD-CVD method, an LPCVD method or the like, which are faster in a film forming speed in conventional film forming methods, in film formation of a barrier film, a working time necessary to fill a trench or the like can be shorter than in a case where all of trenches or recesses of unevenness portions are filled with oxide film layers in the present invention.

A semiconductor device according to still another aspect of the present invention, as in a manufacturing method for a semiconductor device shown in the embodiments of the present invention, includes: a step of preparing semiconductor substrate; and a step of forming an insulator. In the semiconductor substrate preparing step, a semiconductor substrate having a main surface on which unevenness portions are formed is prepared. In the insulator forming step, a step of forming a silicon film using a chemical vapor deposition method on the unevenness portions (recess projection portions) and a step of forming a silicon oxide film by oxidation of the silicon film are alternately repeated several times.

With such a manufacturing method adopted, a semiconductor device having an insulator according to the present invention can be obtained by repeating a process of thermal oxidation of a silicon film or the like of which the oxide film layers are formed after formation of the silicon film of a thickness sufficiently smaller than a width of a recess of an unevenness portion in the interior of the recess. Since, in formation of the silicon film, a film forming method excellent in step coverage can be employed, a risk can be reduced that defects such as a void is formed by blockage in the upper section.

Moreover, even if a void or the like is formed in the interior of a recess in forming the silicon film, a silicon film portion facing the void can be oxidized since oxygen is also supplied to the silicon film portion facing the void by diffusion of oxygen in the silicon film in thermal oxidation of the silicon film. In oxidation of the silicon film, since a volume thereof expands, a void can be made extinct in progress of the volumetric expansion. As a result of the oxidation of a silicon film portion facing a void and the volumetric expansion, an insulator can be obtained without defect such as a void.

Furthermore, in the silicon film oxidation step, a thermal oxidation may be used. Herein, a film quality of a silicon oxide film formed using the thermal oxidation method is more excellent than that of a silicon oxide film formed using an LPCVD method or an HDP-CVD method. Therefore, by using an insulator formed in the above described insulator forming process as an isolation insulator, there can be obtained an isolation insulator having an excellent isolation characteristic.

In a manufacturing method for a semiconductor device according to still another aspect described above, a reaction gas using in a chemical vapor deposition method may include a gas containing an n-type impurity.

In a manufacturing method for a semiconductor device according to still another aspect described above, a step of introducing an n-type impurity element into a silicon film after a step of forming a silicon film and before a step of forming a silicon oxide film may also be performed in the insulator forming step. In the step of introducing an n-type impurity element into a silicon film, a gas containing the n-type impurity element may also be put into contact with the silicon film to thereby introduce the n-type impurity element thereinto.

In a manufacturing method for a semiconductor device according to still another aspect described above, an n-type impurity element may be phosphorus.

In this case, an n-type impurity element such as phosphorus can be easily introduced into a silicon film formed.

Furthermore, in the step of forming a silicon oxide film, an oxidation speed of the silicon film can be improved by incorporating an n-type impurity such as phosphorus into a silicon film in advance. For this reason, a time necessary for forming a silicon oxide film can be shortened.

In a manufacturing method for a semiconductor device according to still another aspect described above, a gas containing an n-type impurity element may be phosphine gas.

In this case, by introducing phosphine gas into a reaction chamber of an apparatus, in which a chemical vapor deposition method (CVD method) is performed, and to form a silicon film therein during formation of a silicon film or after the silicon film is formed, phosphorus can be introduced into the silicon film with ease.

In a manufacturing method for a semiconductor device according to still another aspect described above, the following process conditions may also be adopted in the step of forming an insulator. That is, in the step of forming an insulator, a temperature of a semiconductor substrate may be set in the range of from 520° C. to 750° C., both limits included. A reaction gas used in a chemical vapor deposition method in the step of forming a silicon film may contain monosilane gas. A reaction gas put into contact with the silicon film for oxidizing the silicon film in the step of forming a silicon oxide film may contain a mixed gas of oxygen gas and hydrogen gas in the step of forming an silicon oxide film. A volmetric percentage of hydrogen gas in the mixed gas may be in the range of from 1% to 30%, both limits included.

In this case, there can be certainly performed formation of a silicon film on a semiconductor substrate and thermal oxidation of the silicon film.

A manufacturing method for a semiconductor device according to still another aspect described above may also further include a step of forming a barrier film on an unevenness portion of a semiconductor substrate prior to the insulator forming process.

In this case, since the barrier film works as a barrier against diffusion of an n-type impurity and others in an insulator into a semiconductor substrate, suppression can be realized of diffusion of an n-type impurity element and others contained in the insulator into the semiconductor substrate.

Moreover, in the step of forming a silicon oxide film, there is a case where a stress is produced in a silicon oxide film. In the present invention, however, since a barrier film works as a relaxation layer for the stress in the silicon oxide film, the stress is propagated through a semiconductor substrate to enable a risk of a cause for a defect in the semiconductor substrate to be reduced.

In a manufacturing method for a semiconductor device according to still another aspect described above, the step of preparing a semiconductor substrate may include a step of forming a trench, as a constituent, of an unevenness portion on a main surface of the semiconductor substrate. In addition, in the step of forming a silicon film, the silicon film may be formed in the interior of a trench.

In this case, a lamination body of silicon oxide films obtained in the insulator forming process can be used as a trench isolation insulating film.

According to the present invention, in such away, since an isolation insulator is of a laminated layer structure and oxide film layers of which the laminated layer structure is constructed are formed by a process of oxidizing a polycrystalline silicon of which an oxide film is formed after formation of the polycrystalline silicon film, suppression can be realized of occurrence of a defect such as a void in an isolation insulator. Consequently, suppression can be realized of degradation in isolation characteristic in an isolation insulator.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor substrate having a main surface on which a trench is formed; and
an isolation insulator formed in an interior of said trench using a thermal oxidation method to isolate element forming regions from each other on the main surface of said semiconductor substrate, wherein
said isolation insulator is a lamination body formed by a plurality of oxide film layers.

2. The semiconductor device according to claim 1, further comprising:
a barrier film interposed between an inner wall of said trench and said isolation insulator.

3. The semiconductor device according to claim 2, wherein
said barrier film is a silicon oxide film formed by means of one of a high density plasma chemical vapor deposition method and a low pressure chemical vapor deposition method.

4. The semiconductor device according to claim 1, wherein
said oxide film layers contain an n-type impurity element.

5. The semiconductor device according to claim 4, wherein
said n-type impurity element is phosphorus.

6. The semiconductor device according to claim 4, wherein
a concentration of said n-type impurity element in one oxide film layer among said plurality of oxide film layers is higher than a concentration of said n-type impurity element in another oxide film layer located closer to said semiconductor substrate than said one oxide film layer.

7. A semiconductor device comprising:
a semiconductor substrate having a main surface on which an unevenness portion is formed; and
an insulator formed on said unevenness portion and made of a lamination body formed by a plurality of oxide film layers containing an n-type impurity element.

8. The semiconductor device according to claim 7, wherein
said unevenness portion includes a trench formed on the main surface of said semiconductor substrate, and
said insulator is formed so as to fill said trench.

9. The semiconductor device according to claim 8, further comprising:
a barrier film interposed between an inner wall of said trench and said isolation insulator.

10. The semiconductor device according to claim 9, wherein
said barrier film is a silicon oxide film formed by means of one of a high density plasma chemical vapor deposition method and a low pressure chemical vapor deposition method.

11. The semiconductor device according to claim 7, wherein
said n-type impurity element is phosphorus.

12. The semiconductor device according to claim 7, wherein a concentration of said n-type impurity element in one oxide film layer among said plurality of oxide film layers is higher than a concentration of said n-type impurity element in another oxide film layer located closer to said semiconductor substrate than said one oxide film layer.

13. A manufacturing method for a semiconductor device, comprising the steps of:
preparing a semiconductor substrate having a main surface on which an unevenness portion is formed; and
repeating a step of forming a silicon film on said unevenness portion using a chemical vapor deposition method and a step of forming a silicon oxide film by oxidizing said silicon film, alternately several times.

14. The manufacturing method for a semiconductor device according to claim 13, wherein
in the step of forming said silicon film, a reaction gas used in a chemical vapor deposition method contains a gas containing an n-type impurity element.

15. The manufacturing method for a semiconductor device according to claim 14, wherein
said n-type impurity element is phosphorus.

16. The manufacturing method for a semiconductor device according to claim 15, wherein
the gas containing said n-type impurity element is phosphine gas.

17. The manufacturing method for a semiconductor device according to claim 13, wherein
in said step of forming the insulator, performed is a step of introducing said n-type impurity element into said silicon film by making a gas containing said n-type impurity element into contact with said silicon film after said step of forming the silicon film and before said step of forming the silicon oxide film.

18. The manufacturing method for a semiconductor device according to claim 13, wherein
in said step of forming the insulator, a temperature of said semiconductor substrate is set from equal to or more than 520° C. to equal to or less than 750° C.,
a reaction gas used in a chemical vapor deposition method in said step of forming the silicon film contain monosilane gas,
a reaction gas making into contact with said silicon film for oxidizing said silicon film in the step of forming said silicon oxide film contains a mixed gas of oxygen gas and hydrogen gas, and
a volmetric percentage of said hydrogen gas in said mixed gas is from equal to or more than 1% to equal to or less than 30%.

19. The manufacturing method for a semiconductor device according to claim 13, further comprising a step of forming a barrier film on said unevenness portion of said semiconductor substrate prior to said step of forming the insulator.

20. The manufacturing method for a semiconductor device according to claim 13, wherein
said step of preparing said semiconductor substrate includes: a step of forming a trench included in said unevenness portion on a main surface of said semiconductor substrate, and
in said step of forming the silicon film, said silicon film is formed in an interior of said trench.
